(19) United States
(12) Patent Application Publication
(10) Pub. No.: US 2026/0348847 A1
(43) Pub. Date: Nov. 5, 2026

(54) Examining a Chemical Mechanical Polishing (CMP) Slurry

(71) Applicant: Wolfspeed, Inc., Durham, NC (US)

(72) Inventors: Dinusha Priyadarshani Karunaratne, Cary, NC (US); Simon Bubel, Carrboro, NC (US); Jong Hyup Lee, Cary, NC (US)

(21) Appl. No.: 19/195,030

(22) Filed: Apr. 30, 2025

(51) Int. Cl. G01N 21/47; C09G 1/02

(52) U.S. Cl. CPC G01N 21/47; C09G 1/02; G01N 2223/101

(57) ABSTRACT

A method for examining a chemical mechanical polishing (CMP) slurry is provided. The method comprises transmitting electromagnetic radiation through a sample of the slurry, measuring an interaction between the electromagnetic radiation and the slurry, and making a determination regarding the slurry based on the interaction. The slurry interacts with at least a portion of electromagnetic radiation.

### FIELD

The present disclosure relates generally to semiconductor workpieces and fabrication processes for semiconductor workpieces, such as semiconductor wafers used in semiconductor device fabrication.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

Semiconductor devices may be fabricated from wide bandgap semiconductor materials, such as silicon carbide and/or Group III nitride-based semiconductor materials. The fabrication process for power semiconductor devices may require processing of wide bandgap semiconductor wafers, such as silicon carbide semiconductor wafers.

### SUMMARY

Aspects and advantages of embodiments of the present disclosure will be set forth in part in the following description, or can be learned from the description, or can be learned through practice of the embodiments.

In an aspect, the present disclosure provides an example method for examining a chemical mechanical polishing (CMP) slurry. The method comprises transmitting electromagnetic radiation through a sample of the slurry, measuring an interaction between the electromagnetic radiation and the slurry, and making a determination regarding the slurry based on the interaction. The slurry interacts with at least a portion of electromagnetic radiation.

In another aspect, the present disclosure provides an example slurry recycling system. The system comprises a slurry diversion system configured to receive slurry from at least one chemical-mechanical polishing (CMP) tool; a vessel configured to receive slurry diverted from the at least one CMP tool for reconditioning of the slurry; a slurry monitoring system configured to transmit electromagnetic radiation through a sample of the slurry, measure an interaction of the electromagnetic radiation with the slurry, and determine if the slurry is suitable for recycling; and a slurry redistribution system to provide reconditioned slurry to the at least one CMP tool.

In another aspect, the present disclosure provides an example slurry monitoring apparatus. The apparatus is configured to transmit electromagnetic radiation of a specific wavelength through a sample of a chemical mechanical polishing (CMP) slurry, measure absorbance of the electromagnetic radiation by the slurry, and determine if the slurry is suitable for use.

In another aspect, the present disclosure provides an example method for recycling slurry. The method comprises collecting slurry from at least one chemical-mechanical polishing (CMP) tool, determining a slurry condition by transmitting electromagnetic radiation through a sample of the slurry and measuring an interaction of the electromagnetic radiation with the slurry, and modifying a process operation based on the slurry condition. Modifying the process operation comprises determining if the slurry is suitable for recycling, refreshing the slurry if needed, and providing the collected or refreshed slurry to the at least one CMP tool.

In another aspect, the present disclosure provides an example method for determining the shelf life of a CMP slurry containing a permanganate compound. The method comprises periodically measuring the permanganate concentration of the slurry until it falls beneath a threshold concentration corresponding to a minimum useful permanganate concentration and determining the shelf life based on the time elapsed from the manufacturing of the slurry until the permanganate concentration reached the threshold concentration. Each periodic measurement comprises transmitting electromagnetic radiation through a sample of the slurry, measuring an interaction between the electromagnetic radiation and the slurry, and determining the permanganate concentration based on the interaction. The slurry interacts with at least a portion of electromagnetic radiation.

In another aspect, the present disclosure provides an example predictive project management or factory automation process for a silicon carbide wafer manufacturing facility. The process comprises providing throughput, utilization, or material consumption data of a CMP slurry containing a permanganate compound and examining the CMP slurry by transmitting electromagnetic radiation through a sample of the slurry, measuring an interaction between the electromagnetic radiation and the slurry, and determining the permanganate concentration based on the interaction. The slurry interacts with at least a portion of electromagnetic radiation.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example polishing system for a semiconductor workpiece according to example embodiments of the present disclosure;

FIG. 2 depicts an example slurry monitoring apparatus according to example embodiments of the present disclosure;

FIG. 3 depicts an example slurry monitoring apparatus according to example embodiments of the present disclosure;

FIG. 4 depicts an example slurry monitoring apparatus according to example embodiments of the present disclosure;

FIG. 5 depicts an example slurry monitoring apparatus according to example embodiments of the present disclosure;

FIG. 6A depicts a block diagram of at least a portion of an example CMP slurry recycling system according to example embodiments of the present disclosure;

FIG. 6B depicts a block diagram of at least a portion of an example CMP slurry recycling system according to example embodiments of the present disclosure;

FIG. 6C depicts a block diagram of at least a portion of an example CMP slurry recycling system configured to recycle slurry from a plurality of CMP tools according to example embodiments of the present disclosure;

FIGS. 7A and 7B depict schematic perspective views of an example slurry collection tray suitable for use with the CMP slurry recycling system shown in FIG. 2A, according to example embodiments of the present disclosure;

FIG. 8 depicts a flow chart of an example method for recycling slurry in a CMP tool according to example embodiments of the present disclosure;

FIGS. 9A and 9B depict flow diagrams of at least a portion of an example method for recycling slurry in a CMP tool according to example embodiments of the present disclosure;

FIG. 10 depicts a flow chart of an example method according to example embodiments of the present disclosure; and

FIG. 11 depicts a flow chart of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Power semiconductor devices are often fabricated from wide bandgap semiconductor materials, such as silicon carbide or Group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that example embodiments of the present disclosure may be used with any semiconductor material, such as other wide bandgap semiconductor materials, without deviating from the scope of the present disclosure. Example wide bandgap semiconductor materials include silicon carbide and the Group III-nitrides.

Power semiconductor devices may be fabricated using epitaxial layers formed on a semiconductor workpiece, such as a silicon carbide semiconductor wafer. Power semiconductor device fabrication processes may include surface processing operations that are performed on the silicon carbide semiconductor wafer to prepare one or more surfaces of the silicon carbide semiconductor wafer for later processing steps, such as surface implantation, formation of epitaxial layers, metallization, etc. Example surface processing operations may include grinding operations, lapping operations, and polishing operations.

Aspects of the present disclosure are discussed with reference to a semiconductor workpiece that is a semiconductor wafer that includes silicon carbide (“silicon carbide semiconductor wafer”) for purposes of illustration and discussion. Those of ordinary skill in the art, using the disclosures provided herein, will understand that aspects of the present disclosure can be used with other semiconductor workpieces. Other semiconductor workpieces may include carrier substrates, ingots, boules, polycrystalline substrates, monocrystalline substrates, bulk materials having a thickness of greater than 1 mm, such as greater than about 5 mm, such as greater than about 10 mm, such as greater than about 20 mm, such as greater than about 50 mm, such as greater than about 100 mm to 200 mm, etc.

Methods for surface processing of semiconductor wafers in semiconductor manufacturing may include grinding, lapping, and/or polishing the rough surfaces until a sufficient smoothness and/or thickness is achieved.

Grinding is a material removal process that is used to remove material from the semiconductor wafer. Grinding may be used to reduce a thickness of a semiconductor wafer. Grinding typically involves exposing the semiconductor wafer to an abrasive containing surface, such as grind teeth on a grind wheel. Grinding may remove material of the semiconductor wafer through engagement with the abrasive surface.

Lapping is a precision finishing process that uses a loose abrasive in slurry form. The slurry typically includes coarser particles (e.g., largest dimension of the particles being greater than about 100 microns) to remove material from the semiconductor wafer. Lapping typically does not include engaging the semiconductor wafer with an abrasive-containing surface on the lapping tool (e.g., a wheel or disc having an abrasive-containing surface). Instead, the semiconductor wafer typically comes into contact with a lapping plate or a tile usually made of metal. Lapping typically provides better planarization of the semiconductor wafer relative to grinding.

Polishing is a process to remove imperfections and create a very smooth surface with a low surface roughness. Polishing may be performed using a slurry and a polishing pad. The slurry typically includes finer particles relative to lapping, but coarser particles relative to chemical mechanical planarization (CMP). Polishing typically provides better planarization of the semiconductor wafer relative to grinding.

CMP is a type of fine or ultrafine polishing, typically used to produce a smoother surface ready, for instance, for epitaxial growth of layers on the semiconductor wafer. CMP may be performed chemically and/or mechanically to remove imperfections and to create a very smooth and flat surface with low surface roughness. CMP typically involves changing the material of the semiconductor through a chemical process (e.g., oxidation) and removing the new material from the semiconductor wafer through abrasive contact with a slurry and/or other abrasive surface or polishing pad (e.g., oxide removal). In CMP, the abrasive elements in the slurry typically remove the product of the chemical process and do not remove the bulk material of the semiconductor wafer, often leaving very low subsurface damage.

Polishing tools (e.g., such as chemical mechanical planarization (CMP) tools) may be used after grinding operations to polish and/or smooth a semiconductor wafer surface. Polishing tools, such as CMP tools, may use a combination of chemical and mechanical forces to remove excess materials from a wafer surface, ensuring desired flatness and smoothness. Polishing tools, such as CMP tools, may include a rotating platen, polishing pad, and a slurry containing abrasive particles and chemical agents. As the wafer is pressed against the polishing pad and rotated, the slurry chemically reacts with and/or mechanically removes material, resulting in a highly planar and smooth surface.

Quality control of the CMP slurry may be important for maintaining desired material removal rates during a CMP process. Typically, slurries for CMP of silicon carbide wafers and other workpieces contain an oxidizing agent, such as a permanganate compound. They may also contain abrasive particles. As a slurry degrades during use, transportation, or storage, permanganate compounds can degrade to form manganese dioxide (MnO₂). Therefore, determining the quality of the slurry typically requires quantification of the concentration of permanganate compounds in the slurry. Quantification of permanganate content in permanganate-based SiC CMP slurries typically involves polishing tests to determine material removal rate (MRR). If the MRR is within a prescribed range or if the MRR remains constant over time, it is assumed that the permanganate concentration remains the same. While such indications can provide general information about the state of the slurry, they do not provide precise data.

Laboratory techniques may also be used to more accurately quantify the permanganate concentration. For example, one laboratory technique used to determine permanganate concentration is based on titrations with an acidic reducing agent and detecting the end point based on color change or pH change. However, titration using other chemicals and end point detection based on color/pH change is not straightforward. Therefore, it is not a method which can be used to determine real-time (i.e., in-line) slurry degradation or which can be replicated readily enough for efficient quality control at larger scales.

For the above reasons, there is a need for a more efficient, easily repeatable method for examining SiC CMP slurries which can optionally be used in real time to provide more accurate data than current in-situ methods are capable of providing.

In this regard, example aspects of the present disclosure are directed to systems and methods for examining SiC CMP slurries using spectrophotometric methods, which may be based on the well-known Beer-Lambert law. For example, from the Beer-Lambert law, it is known that when the light of a specific wavelength passes through a solution containing a colored compound, the amount of light absorbed by the colored compound is directly proportional to the concentration of the light absorbing species in the sample.

In permanganate based SiC CMP slurries, purple permanganate solutions show characteristic absorption peaks in the wavelength range of 500-570 nm, which can be used for spectrophotometric quantification of permanganate in the slurry. For example, in the case of constant or negligible light scattering effects by species other than MnO₂, the absorbance of known concentrations of permanganate solutions at a specific wavelength can be used to create a calibration curve by plotting absorbance vs permanganate concentration. The concentration of permanganate in the slurry being measured can be determined by measuring the absorbance of the sample at the same wavelength and calculating the concentration based on the calibration curve.

Similarly, per the Beer-Lambert law, the light scattering caused by any suspended solids in a suspension is proportional to the concentration of suspended materials in the sample. For permanganate-based CMP slurries, when the permanganate in the slurry degrades, it forms manganese dioxide (MnO₂) as a suspended solid. Therefore, by measuring the scattering of light over time, correlating to MnO₂ formation over time, slurry degradation can be measured. As MnO₂ formation is directly correlated to permanganate concentration drop, this data can be used to determine the lost (degraded) KMnO₄ concentration.

In the case of variable or non-negligible light scattering effects from components other than MnO₂ in the range of the relevant light wavelength (e.g., in the range of 500 nm to 570 nm), the calculation of permanganate concentration can be done via absorbance measurements and back calculations of the absorption via an additional scattering coefficient that may be determined separately or assumed constant, or via plotting the absorbance as -log(R+T) with R being the reflected light and T the transmitted light.

As mentioned above, currently used methods for examining SiC CMP slurries are not straightforward to get direct feedback on permanganate concentration. Advantageously, the systems and methods described herein can directly determine permanganate concentration and can be applied to quality control of slurries prior to use or as an in-line, real-time metrology method connected to a slurry distribution and/or recycling system. When the methods described herein are used to examine slurries stored prior to use, the data can be used to determine typical shelf life of the slurries.

In some embodiments, a spectrophotometric method can be used to determine permanganate concentrations in abrasive free slurries (i.e., slurries containing no added abrasives and thus no interference from light scattering by any suspended solids) by measuring the absorbance at a specific wavelength that is absorbed by a purple permanganate solution. As used herein, an abrasive free slurry may contain MnO₂ which is a degradation product of permanganate compounds but does not contain additional intentionally added abrasive particles.

In some embodiments, abrasive-free slurry degradation can be determined by measuring MnO₂ formation by measuring scattering and correlating it the suspended solid concentration.

In some embodiments, permanganate in the slurry can be quantified using an in-line spectrophotometric unit attached to a slurry distribution system or slurry recycling system. The unit can determine whether the permanganate concentration has dropped below a designated threshold limit and provide this information to a feedback loop to decide if the slurry is suitable for use or if it needs be treated or replaced.

In some embodiments, a spectrophotometric method can be applied to permanganate slurries with added abrasives. In such embodiments, the sample can be centrifuged to separate the solids. The supernatant solution can then be used for spectrophotometric detection of permanganate.

In some embodiments, the slurry sample collected for testing can be diluted prior to examination to reduce the interference coming from light scattering species in the slurry and/or to reduce the KMnO₄ concentration if it is higher than the measurable range. In such embodiments, a dilution factor can be incorporated into the calculation of the concentration in the initial (undiluted) sample.

The systems and methods described herein can be performed using a spectrometer, such as a fiber spectrometer, a micro spectrometer, or another spectrometer. Some embodiments include the use of one or more light sensitive diodes and illumination via an GaN/SiC, GaN/Sapphire, InGaN/Sapphire or GaP/GaP LED light source. One or more spectral filters may be used in the optical line. In some embodiments, the transmitted and reflected light is captured, either entirely or partially. For example, an integrating sphere, a goniometer, or a movable mirror arrangement may be used.

In some embodiments, the permanganate absorption response may be collected as part of another optical metrology system, such as dynamic light scattering, FTIR, Raman, large spectrum analysis, scatterometry, or a camera system (e.g., used to monitor flow or particles).

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

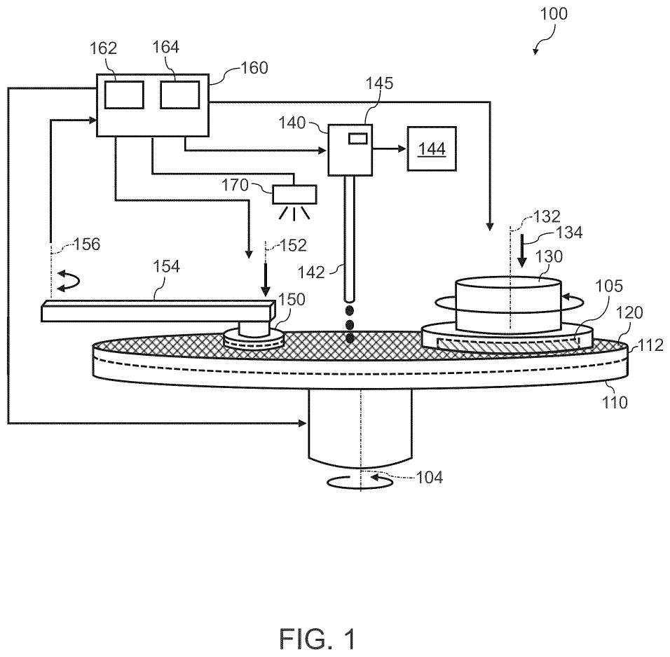

FIG. 1 depicts an example polishing system 100 for a semiconductor workpiece (e.g., silicon carbide wafer) 105 according to example embodiments of the present disclosure. The polishing system 100 is a CMP system operable to perform one or more polishing operations for a silicon carbide wafer 105. The silicon carbide wafer 105 may include 4H silicon carbide, 6H silicon carbide, or another crystal structure. The silicon carbide wafer 105 may be an on-axis workpiece (e.g., end face parallel to the (0001) plane) or an off-axis workpiece (e.g., end face non-parallel to the (0001) plane). The polishing operation may be performed on a carbon face or a silicon face of the silicon carbide wafer 105. The silicon carbide wafer 105 may be doped or undoped. In some embodiments, the silicon carbide wafer has a diameter from about 100 mm to about 300 mm, such as about 100 mm, such as about 150 mm, such as about 200 mm. In some examples, the polishing system 100 includes a platen 110 with a polishing pad 120, a workpiece carrier 130, a delivery system 140, a pad conditioner 150, and a controller 160.

More specifically, the polishing system 100 includes the platen 110. The platen 110 may be operable to rotate about an axis 104. The platen 110 may be operable to rotate about the axis 104 in either a clockwise or counterclockwise direction. In some examples, the platen 110 may rotate, for instance, at a rotational speed in a range of about 10 rpm to about 10000 rpm, such as about 10 rpm to about 7500 rpm, such as about 10 rpm to about 2000 rpm, such as about 10 rpm to about 1000 rpm, such as about 10 rpm to about 500 rpm, such as about 10 rpm to about 120 rpm.

The platen 110 may include a receptacle 112. The receptacle 112 may be configured to hold a polishing pad 120 for a CMP process. The receptacle 112 may be a surface configured to support or receive the polishing pad 120. In some examples, the receptacle 112 may be a planar surface that supports the polishing pad 120.

The polishing pad 120 may provide a surface for polishing the silicon carbide semiconductor wafer 105. The polishing pad 120 may include durable and chemically resistant materials such as polyurethane and/or polyether ether ketone (PEEK) material. The polishing pad 120 may have a surface with a specified roughness and porosity to facilitate polishing a silicon carbide semiconductor wafer 105. The polishing pad 120 may include grooves or dimples to increase slurry distribution and reduce edge effects during the CMP process. The polishing pad 120 may include a cushioning layer (e.g., foam or rubber), in some examples, to facilitate adaptation of the polishing pad 120 to the topography of the semiconductor wafer 105, providing improved planarity of the semiconductor wafer 105.

The polishing pad 120 may have a diameter. The diameter may be greater than a size of the silicon carbide semiconductor wafer 105. The polishing pad 120 may have a diameter in a range of, for instance, about 150 mm to about 820 mm, such as in a range of about 150 mm to about 400 mm, such as in a range of about 150 mm to about 300 mm. In some examples, the diameter of the polishing pad 120 may be smaller or nearly the same size as the diameter of the platen 110 (FIG. 1). However, the diameter of the polishing pad 120 may be larger than the diameter of the platen 110 without deviating from the scope of the present disclosure. In some examples, the polishing pad 120 may have a thickness in a range of about 2 mm to about 40 mm, such as in a range 3 mm to about 20 mm, such as in a range of about 50 mm to about 10 mm.

In some examples, the polishing system 100 includes a slurry delivery system 140. The slurry delivery system 140 may be used to deliver a slurry to the polishing pad 120 on the platen 110 during a CMP process, for instance, from a slurry delivery outlet 142. In some embodiments, the slurry delivery outlet 142 may include a nozzle for delivering the slurry. In some examples, the slurry may include an oxidizing agent. In some example embodiments, the oxidizing agent may include sodium permanganate and/or potassium permanganate and optionally one or more other oxidizing agents. Other suitable slurries with one or more abrasive elements (e.g., abrasive particles) may be used without deviating from the scope of the present disclosure.

In some examples, the slurry delivery system 140 may include an additive delivery system 145 configured to deliver one or more additives (e.g., oxidizing material, oxide removal material) either with the slurry through the slurry delivery outlet 142 or separate from the slurry through an additional fluid delivery outlet.

Aspects of the present disclosure are discussed with reference to providing a slurry to the polishing pad 120 through fluid delivery outlet 142 for purposes of illustration and discussion. Those of ordinary skill in the art, using the disclosures provided herein, will understand that the slurry delivery system 140 may deliver the slurry to the polishing pad 120 in various ways without deviating from the scope of the present disclosure, such as from a plurality of fluid delivery outlets, from apertures in the platen and/or the polishing pad, or from other fluid delivery techniques.

In some examples, the polishing system 100 includes a workpiece carrier 130. The workpiece carrier 130 is operable to bring one or more silicon carbide semiconductor wafers 105 into contact with the polishing pad 120 to implement a polishing process. In some examples, the workpiece carrier 130 may be operable to hold a single silicon carbide semiconductor wafer 105 for single wafer processing. In some examples, the workpiece carrier 130 may be operable to hold a plurality of silicon carbide semiconductor wafers 105 for batch processing. The methods described herein, in some instances, are particularly useful for single wafer processing due to the need for improved efficiency to increase throughput. However, the methods are similarly useful for batch processing.

The workpiece carrier 130 may be operable to rotate the silicon carbide semiconductor wafer 105 about an axis 132. The axis 132 is not aligned with the axis 104 associated with the platen 110. The workpiece carrier 130 may be operable to rotate the silicon carbide semiconductor wafer 105 about the axis 132 in either a clockwise or counterclockwise direction. In some examples, the workpiece carrier 130 may rotate, for instance, at a rotational speed in range of about 10 rpm to about 10000 rpm, such as about 10 rpm to about 7500 rpm, such as about 10 rpm to about 2000 rpm, such as about 10 rpm to about 1000 rpm, such as about 10 rpm to about 500 rpm, such as about 10 rpm to about 120 rpm. The workpiece carrier 130 may rotate in the same direction as the platen 110 or in a different direction relative to the platen 110.

The workpiece carrier 130 may be able to provide a downforce 134 of the silicon carbide semiconductor wafer 105 against the polishing pad 120. The downforce 134 of the workpiece carrier 130 may be controlled to adjust the polishing rate of the polishing process of the silicon carbide semiconductor wafer 105.

The workpiece carrier 130 may also oscillate in a lateral direction along the surface of the polishing pad 120. This will allow exposure of the semiconductor wafer 105 to different portions of the polishing pad 120 (e.g., at different radii of the polishing pad 120) during a polishing operation.

The polishing system 100 may include a pad conditioner 150. The pad conditioner 150 may rotate about an axis 152, such that the pad conditioner 150 rotates along the surface of the polishing pad 120 (e.g., in either a clockwise or counterclockwise direction). In some examples, the pad conditioner 150 may be on a swing arm 154 that may swing about an axis 156 to move the pad conditioner 150 to different locations on the polishing pad 120. The pad conditioner 150 may include an abrasive-containing material having one or more abrasive elements (e.g., diamond) that are used to condition or dress the polishing pad 120 as the polishing pad 120 is subject to glazing during a polishing process. In some embodiments, the abrasive elements may include one or more of: (i) diamond; (ii) ceramic; (iii) metal carbide; (iv) metalloid nitride (e.g., silicon nitride); (v) metalloid oxide; (vi) metalloid carbide (e.g., silicon carbide); (vii) carbon group nitride; (viii) carbon group oxide; (ix) carbon group carbide, (x) boron nitride (e.g., c-BN or w-BN), or any other suitable abrasive materials having a similar hardness.

The system 100 can additionally include a slurry monitoring system 144. Slurry monitoring system 144 can examine the slurry by the methods described herein. As will be discussed in further detail below, slurry monitoring system 144 can be used to determine whether the slurry meets desired specifications or whether it has been degraded. If the slurry meets the desired specifications, it can continue to be used by system 100. However, if it has been degraded past a prescribed threshold, it can be removed and replaced by fresh slurry or it can be treated or refreshed such that it can be placed back in use.

The system 100 includes one or more control devices, such as a controller 160. The controller 160 may include one or more processors 162 and one or more memory devices 164. The one or more memory devices 164 may store computer-readable instructions that when executed by the one or more processors 162 cause the one or more processors 162 to perform one or more control functions, such as any of the functions described herein. The controller 160 may be in communication with various other aspects of the system 100 through one or more wired and/or wireless control links. For instance, the controller 160 may control the platen 110, the workpiece carrier 130, the slurry delivery system 140, the slurry monitoring system 144, and/or the pad conditioner 150 to implement polishing processes according to examples of the present disclosure.

For instance, in some examples, the controller 160 may control the slurry delivery system 140 to deliver one or more materials to the polishing pad 120. For instance, the controller 160 may control the slurry delivery system 140 to provide an oxidizing slurry to the polishing pad 120 (e.g., through slurry delivery outlet 142).

The controller 160 may control the slurry monitoring system 144 as well. For example, the controller may control when to deliver slurry to the slurry monitoring system 144, determine whether the slurry is suitable to remain in use or whether it should be refreshed or discarded, and control any refreshing or recycling process required based on the determination.

As shown in FIG. 1, in some examples, the system 100 may include a sensor 170. The sensor 170 is configured to measure a process condition. For example, the process condition may be a temperature of the polishing pad 120, a roughness of the silicon carbide workpiece 105, a roughness of the polishing pad 120, a wear condition of the polishing pad 120, or other parameter. When the process condition is the temperature of the polishing pad 120, the sensor 170 may be a temperature sensor, such as a non-contact infrared thermometer. When the process condition is surface roughness of the silicon carbide workpiece 105 or the polishing pad 120, the sensor 170 may be an optical sensor configured to measure the surface roughness. The controller 160 may be configured to receive information about the process condition from the sensor 170 and determine whether to divert slurry to the slurry monitoring system.

In some embodiments, for instance, the controller 160 may be configured to divert slurry to the slurry monitoring system when the temperature of the polishing pad 120 reaches a set threshold temperature. The threshold temperature may be correlated to the degradation temperature of the various components contained in the slurry. In some embodiments, the threshold temperature can be from about 40 °C to about 55 °C, in some embodiments from about 40 °C to about 50 °C, in some embodiments from about 40 °C to about 45 °C, in some embodiments from about 45 °C to about 55 °C, and in some embodiments, from about 50 °C to about 55 °C.

In other embodiments, the controller 160 may be configured to divert slurry to the slurry monitoring system 144 after a set period of time since starting the polishing operation or at set time intervals throughout the duration of the polishing operation.

The controller 160 may be configured to enact examination of the slurry after polishing each workpiece in a series of workpieces. For example, when polishing a plurality of silicon carbide workpieces in series, slurry monitoring can be performed between polishing of each workpiece.

In other embodiments, the controller 160 may be configured to enact examination of the slurry after a set number of workpieces have been polished within a series of workpiece polishing operations. For example, the controller 160 may be configured to divert slurry to the slurry monitoring system 144 after polishing every 2 workpieces, such as after polishing every 3 workpieces, such as after polishing every 4 workpieces, such as after polishing every 5 workpieces, such as after polishing every 6 workpieces, such as after polishing every 7 workpieces, such as after polishing every 8 workpieces, such as after polishing every 9 workpieces, such as after polishing every 10 workpieces.

The controller 160 may be configured to control various other parameters of the polishing, slurry examination, and slurry diversion and recycling processes as well. For example, the controller 160 may be configured to control one or more of the addition of fresh slurry, addition of a dilutant or additive, or polishing parameters such as process step durations, flow rates, speeds, pressures, and temperature regulating, or rinsing, cleaning, and conditioning processes.

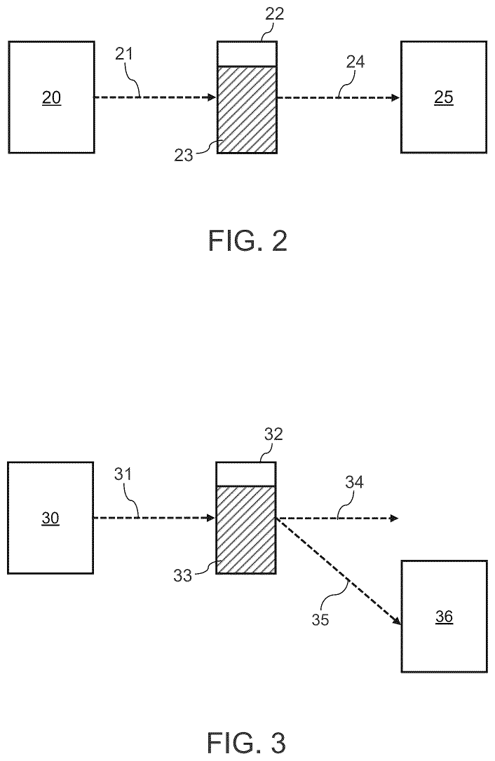

FIG. 2 shows a slurry monitoring apparatus which includes an electromagnetic radiation source 20 which can transmit electromagnetic radiation 21. The electromagnetic radiation 21 can pass through vessel 22 containing the slurry 23. The slurry monitoring apparatus also includes a detector 25 which can measure the intensity of of the electromagnetic radiation 24 after it has passed through the slurry sample and can therefore determine the absorbance of the electromagnetic radiation by the slurry sample.

The electromagnetic radiation source 20 can produce a monochromatic beam of radiation directed toward the vessel 22 containing the slurry 23. The electromagnetic radiation source 20 is not limited. For example, in some embodiments, the electromagnetic radiation source 20 may include an LED light source, such as a GaN/SiC, GaN/Sapphire, InGaN/Sapphire or GaP/GaP LED light source. The electromagnetic radiation source 20 may include one or more focusing elements and/or spectral filters in the optical line as is known in the art to produce a beam of monochromatic light of the desired wavelength in the direction of the slurry sample.

The specific wavelength of electromagnetic radiation transmitted to the slurry sample may be any that may interact with a species in the slurry, particularly in a manner in which the level of interaction (e.g., absorbance or scattering) is correlated with the concentration of that species in the slurry. For example, when examining the slurry for the concentration of a permanganate compound, the specific wavelength may be in the visible light spectrum, and more particularly in the range from about 500 nm to about 570 nm. It should be understood that electromagnetic radiation at other wavelengths and in other parts of the spectrum (e.g., UV, infrared, etc.) may be used to the extent that there is a correlation between an interaction and a concentration of a species being measured.

The vessel 22 may be any transparent vessel suitable for performing spectrophotometry, such as a cuvette. The vessel 22 contains the slurry sample 23. The slurry sample 23 may include a solvent or carrier (e.g., water), an oxidizing agent, and optionally abrasive particles.

In some embodiments, the solvent is a polar solvent. For example, in some embodiments, the solvent is water, such as deionized water. In other embodiments, the solvent is an organic solvent. For example, in some embodiments, the solvent is a polar aprotic organic solvent, such as N,N-dimethylformamide (DMF), acetonitrile (MeCN), tetrahydrofuran (THF), dimethylsulfoxide (DMSO), 1,2-Dimethoxyethane (DME), or dichloromethane (DCM). In other embodiments, the solvent is a polar protic solvent, for example, an alcohol, such as isopropanol or a glycol. In other embodiments, the solvent can be a nonpolar organic solvent, such as 1,4-difluorobenzene or dipropyl ether (DPE). In some embodiments, the solvent comprises mixtures of one or more of such solvents.

The abrasive particle may include silica, ceria, zirconia, alumina, silicon carbide, nitrates, and/or other carbides and in general one or more of: (i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide.

In some embodiments, particularly when the semiconductor workpiece is a silicon carbide workpiece, the oxidizing agent contains permanganate ions, such as those from sodium permanganate and/or potassium permanganate. The slurry may also contain degradation products, such as MnO₂ formed from the degradation of permanganate oxidizers.

For slurries containing abrasive particles, the abrasive particles can be removed from the slurry prior to testing to eliminate or reduce any interfering effects that they might have to the spectrophotometric process. Removal may include a filtering or centrifugation process. For example, the slurry can be separated by a centrifuge and the supernatant can be used as the slurry sample 23 for examination.

The detector 25 can measure the intensity of the electromagnetic radiation 24 that passes through the slurry sample. Any suitable detector for the type of electromagnetic radiation emitted from the electromagnetic radiation source 20 can be used. For example, in the case of an LED light source, the detector may include one or more light sensitive diodes, which can produce an electrical signal proportional to the intensity of the light emitted. Absorbance can then be determined from the difference between the strength of the light transmitted to the sample to the strength of the light detected after passing through the sample.

The slurry monitoring apparatus including the electromagnetic radiation source 20 and the detector 25 may be a spectrophotometer, such as a fiber spectrometer or a micro spectrometer. In some embodiments, the apparatus may be capable of measuring both transmitted and reflected light. For example, the apparatus may include an integrating sphere, goniometer, or movable mirror arrangement.

The output from the detector 25 can be used to determine a concentration of one or more components in the slurry. For example, when measuring the concentration of a permanganate compound in the slurry, if all other aspects of the slurry are equal, the concentration of the permanganate compound is directly proportional to the amount of light absorbed. Therefore, the slurry monitoring system can be calibrated for a specific type of slurry by creating a calibration curve of light absorbance vs permanganate concentration by measuring the absorbance of two or more standard slurries (i.e., slurries with known permanganate concentrations). The concentration of permanganate in the standard slurries can be measured using another technique, such as titration. Once a calibration curve is produced, the permanganate concentration of another slurry of that type can be determined by measuring the absorbance and using the calibration curve to determine the corresponding permanganate concentration. In some embodiments, the slurry monitoring system may include a processor configured to make this determination from the output of the detector 25. In some embodiments, the processor may be processor 162 associated with controller 160 (FIG. 1).

In some embodiments, the slurry monitoring apparatus can determine whether the slurry is suitable for use or if it needs to be discarded or refreshed. For example, if the permanganate concentration is within a prescribed threshold range, the slurry can be considered suitable for use, and if the permanganate concentration is outside the prescribed threshold range, the slurry can be determined to need discarding or refreshing. Similarly, rather than having a prescribed permanganate concentration range, the range can simply be based on the absorbance value (i.e., a prescribed absorbance threshold), as the two are correlated.

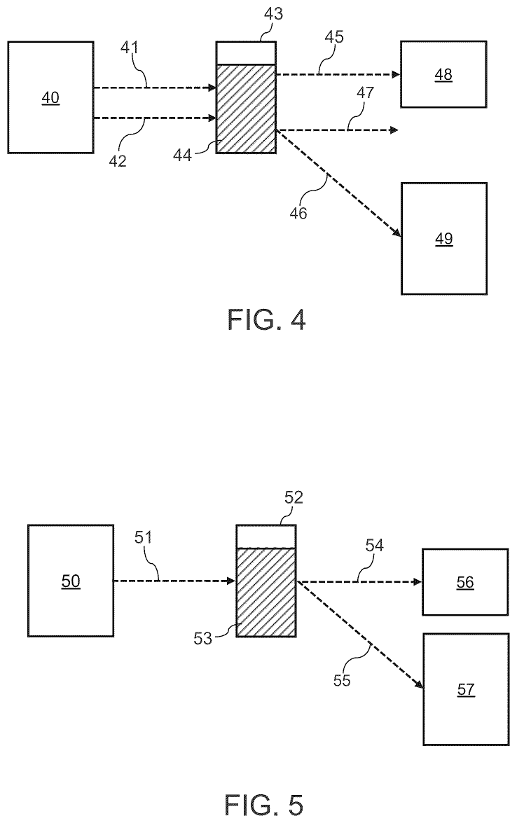

FIG. 3 shows another embodiment of a slurry monitoring system including an electromagnetic radiation source 30 which can transmit electromagnetic radiation 31. The electromagnetic radiation 31 can pass through vessel 32 containing the slurry 33. The slurry monitoring apparatus also includes a detector 36 which can measure the intensity of the electromagnetic radiation 35 deflected after interacting with the slurry sample and therefore the scattering level of the electromagnetic radiation by the sample. A separate portion of the electromagnetic radiation 34 may pass through the slurry sample without being deflected.

The electromagnetic radiation source 30, vessel 32, slurry 33, and detector 36 may be any of the types discussed for electromagnetic radiation source 20, vessel 22, slurry 23, and detector 25 in FIG. 2. However, in the slurry monitoring apparatus shown in FIG. 3, the detector is located at an angle relative to the incoming light path rather than being located directly in the initial light path direction on the opposite side of the slurry sample. As such, the detector 36 can measure the amount of the electromagnetic radiation (e.g., visible light of a specific wavelength) scattered by the sample, as is known in the art.

Measuring the scattering of electromagnetic radiation as it is transmitted through a slurry sample can indicate the concentration of solid particles suspended in the slurry. For example, the light scattering caused by any suspended solids in a suspension is proportional to the concentration of suspended materials in the sample. If the slurry sample is generally free of abrasive particles (i.e., those intentionally added to a CMP slurry), then the likely source of solid particles in the sample is from degraded permanganate compounds in the form of MnO₂. Therefore, the slurry monitoring system can be calibrated for a specific type of slurry by creating a calibration curve of light scattering vs MnO₂ concentration by measuring the scattering of two or more standard slurries (i.e., slurries with known MnO₂ concentrations). Once a calibration curve is produced, the MnO₂ concentration of another slurry of that type can be determined by measuring the scattering and using the calibration curve to determine the corresponding MnO₂ concentration. In some embodiments, the slurry monitoring system may include a processor configured to make this determination from the output of the detector 36. In some embodiments, the processor may be processor 162 associated with controller 160 (FIG. 1).

In some embodiments, the concentration of MnO₂ does not need to be specifically determined. For example, as a slurry degrades over time, the scattering level increases as more MnO₂ is produced. In this regard, the scattering level over time can be tracked by measuring a series of slurry samples collected at different times, and a threshold for the change in scattering level compared to a baseline level (i.e., that of a nondegraded slurry) can be set. When the change in scattering level exceeds that threshold, the slurry can be considered out of spec and in need of replacement or refreshment. In some embodiments, the slurry monitoring apparatus is configured to make such determinations.

Similarly, the concentration of permanganate compounds can be determined based on the scattering detected by determining the concentration of MnO₂ as described above and back-calculating the permanganate compound concentration from a known starting concentration of the permanganate concentration, because the MnO₂ concentration in a slurry is inversely proportional to the permanganate concentration.

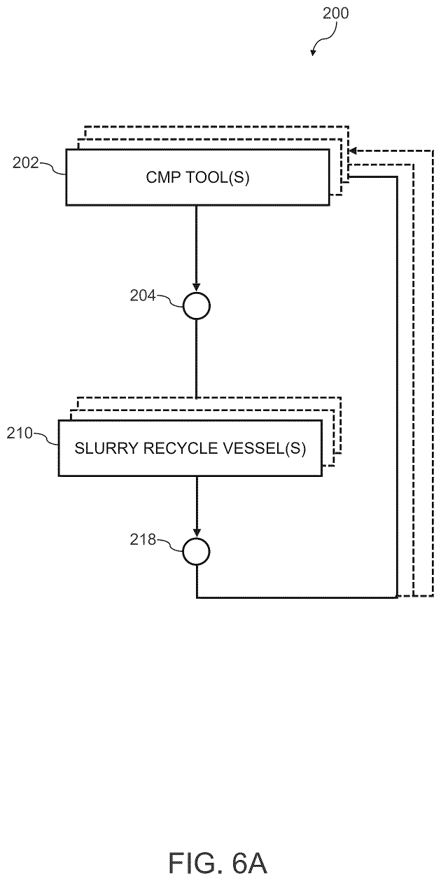

FIG. 4 shows a slurry monitoring apparatus which combines absorbance measurement with scattering measurement. The apparatus includes an electromagnetic radiation source 40 which can transmit a first beam of electromagnetic radiation 41 having a first wavelength. The electromagnetic radiation 41 can pass through vessel 43 containing the slurry 44. The slurry monitoring apparatus also includes a first detector 48 which can measure the intensity of the electromagnetic radiation 45 which passes through the slurry sample and therefore the absorbance of the electromagnetic radiation by the slurry sample. The electromagnetic radiation source 40 can also transmit a second beam of electromagnetic radiation 42 having a second wavelength. The slurry monitoring apparatus also includes a second detector 49 which can measure the intensity of the electromagnetic radiation 46 deflected after interacting with the slurry sample and therefore the scattering level of the electromagnetic radiation by the sample. A separate portion of the electromagnetic radiation 47 may pass through the slurry sample without being deflected.

The electromagnetic radiation source 40, vessel 43, slurry 44, and detectors 48 and 49 may be any of the types discussed for electromagnetic radiation source 20, vessel 22, slurry 23, and detector 25 in FIG. 2.

The slurry monitoring apparatus of FIG. 4 can be used to measure the concentration of two different components in the slurry which cause different interactions with electromagnetic radiation. For example, by measuring the absorbance of the first wavelength, a concentration of a component which absorbs electromagnetic radiation at that wavelength can be determined, as discussed above with respect to FIG. 2. By measuring the scattering of electromagnetic radiation of the second wavelength, the concentration of suspended solids can be determined, as discussed with respect to FIG. 3. For example, the concentration of a permanganate compound can be measured using the absorbance calculated from the output of detector 48 and the concentration of MnO₂ can be measured using the scattering calculated from the output of detector 49.

The first wavelength may be in the range of about 500 nm to about 570 nm, corresponding to absorption peaks of permanganate solutions and the second wavelength may be outside of that range, for example, in a range not absorbed by permanganate solutions. The first and second beams of electromagnetic radiation may be produced by separate sources or may share a single source but different focusing elements and spectral filters.

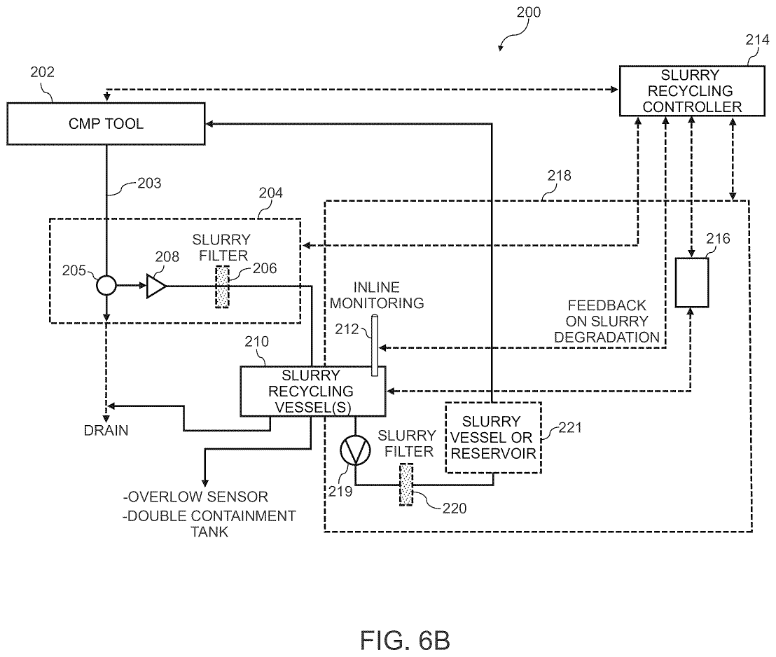

FIG. 5 shows another slurry monitoring apparatus which combines absorbance measurement with scattering measurement. The apparatus includes an electromagnetic radiation source 50 which can transmit a first beam of electromagnetic radiation 51 having a specific wavelength. The electromagnetic radiation 51 can pass through vessel 52 containing the slurry 53. The slurry monitoring apparatus also includes a detector 56 which can measure the intensity of the electromagnetic radiation 54 which passes through the slurry sample and therefore the absorbance of the electromagnetic radiation by the slurry sample. The slurry monitoring apparatus also includes a second detector 57 which can measure the intensity of the electromagnetic radiation 55 deflected after interacting with the slurry sample and therefore the scattering level of the electromagnetic radiation by the sample.

The electromagnetic radiation source 50, vessel 52, slurry 53, and detectors 56 and 57 may be any of the types discussed for electromagnetic radiation source 20, vessel 22, slurry 23, and detector 25 in FIG. 2.

The slurry monitoring apparatus of FIG. 5 can also be used to measure the concentration of two different components in the slurry which cause different interactions with electromagnetic radiation. For example, by measuring absorbance, a concentration of a component which absorbs electromagnetic radiation at that wavelength can be determined, as discussed above with respect to FIG. 2. By measuring scattering, the concentration of suspended solids can be determined, as discussed with respect to FIG. 3. For example, the concentration of a permanganate compound can be measured using the absorbance calculated from the output of detector 56 and the concentration of MnO₂ can be measured using the scattering calculated from the output of detector 57. The slurry monitoring apparatus of FIG. 5 is similar to that of FIG. 4 except that it uses light of a single wavelength and measures both absorption and scattering effects at that wavelength.

In some embodiments, the absorbance value may be higher than it should be for the permanganate concentration in the slurry due to interference by light scattering species. In such embodiments, the calculated KMnO₄ concentration can be inaccurate. However, the scattering response from the second output (e.g., measured by second detector 57) can be used to make a background correction to subtract the scattering interference from the first absorbance measurement used to determine the permanganate concentration.

The slurry monitoring apparatuses of FIGS. 2-5 can be standalone systems for examining CMP slurries or they can be incorporated into CMP polishing systems, such as polishing system 100 described with respect to FIG. 1. For example, the slurry monitoring apparatuses of FIGS. 2-5 can be included in the slurry monitoring system 144 in FIG. 1.

In some embodiments, a slurry monitoring system is used to check the quality of slurries before use. For example, slurries can be examined after being transported or stored to determine whether they are suitable for use. Measurements may be made over time while slurries are being stored in order to determine an acceptable storage time (i.e., shelf life) as part of a quality control program.

In other embodiments, a slurry monitoring system or apparatus as described herein may be incorporated into a CMP system and used for in-line metrology. In some embodiments, for example, the slurry monitoring apparatus may be part of a slurry recycling system.

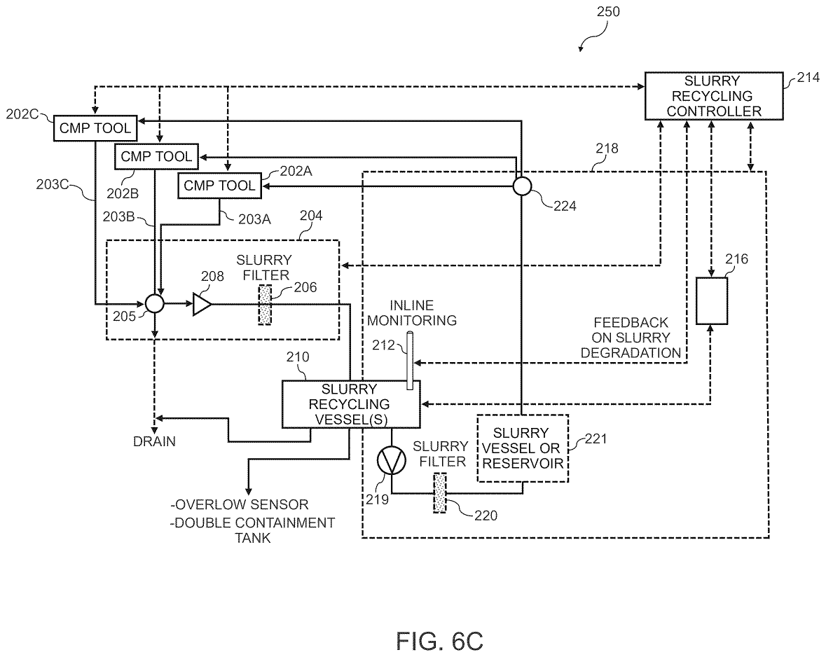

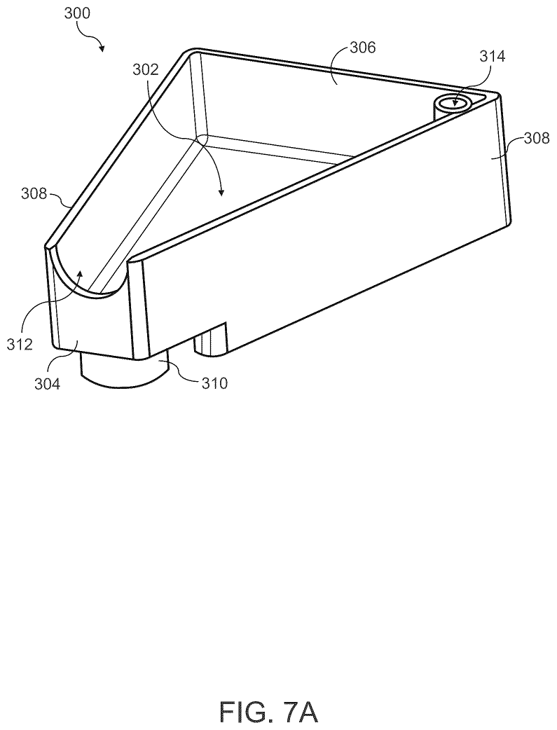

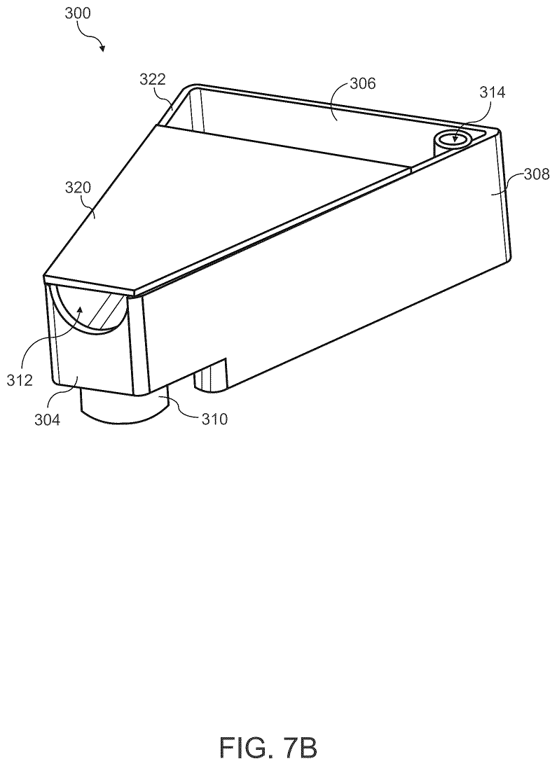

FIG. 6A is a block diagram depicting at least a portion of an example CMP slurry recycling system 200. Referring to FIG. 2A, the CMP slurry recycling system 200 includes at least one CMP tool 202, which may be a single-wafer CMP toolset adapted to process SiC wafers, although embodiments are not limited thereto. The CMP slurry recycling system 200 further includes a slurry diversion mechanism 204 configured to receive slurry from the CMP tool 202 and provide the collected slurry to at least one slurry recycle vessel 210.

In one or more embodiments, the slurry diversion mechanism 204 may comprise a valve (e.g., diverter valve) configured to selectively open during a prescribed stage (e.g., an intermediate stage) of a CMP processing cycle for providing the received slurry to the slurry recycle vessel(s) 210. In some embodiments, the slurry diversion mechanism 204 may be integrated with the CMP tool 202. In some embodiments, the slurry diversion mechanism 204 may comprise a blocking element configured to enable collection of slurry during the prescribed stage of the CMP processing cycle and to disable (i.e., stop or block) the collection of slurry when the CMP tool is operating outside of the prescribed stage of the CMP processing cycle.

The CMP slurry recycling system 200 further includes a slurry redistribution mechanism 218 configured to receive slurry from the slurry recycle vessel(s) 210 and to provide reconditioned (i.e., refreshed) slurry to the CMP tool(s) 202. The slurry redistribution mechanism 218 may be configured to measure or monitor one or more properties of the received slurry in the slurry recycle vessel(s) 210 and to refresh or recondition the slurry when one or more of the measured properties is outside of a prescribed threshold or range. For example, the slurry redistribution mechanism 218 may include a slurry monitoring apparatus as discussed above with respect to FIGS. 2-5. In this regard, the property measured may be the concentration of a permanganate compound and/or a degradation product thereof. In one or more embodiments, refreshing of the slurry may include performing additive reconditioning of the slurry in the vessel 210; that is, adding something (e.g., a solution) to the slurry to change one or more properties of the slurry (e.g., permanganate concentration). In other embodiments, subtractive and/or additive reconditioning of the slurry may be performed; that is, adding something to or removing something from (e.g., filtering) the slurry to change one or more properties of the slurry.

FIG. 6B is a block diagram depicting at least a portion of an example embodiment of the CMP slurry recycling system 200 of FIG. 6A. Referring to FIG. 6B, the CMP slurry recycling system 200 includes at least one CMP tool 202. The CMP tool 202 may include a slurry collection mechanism 203, which may comprise, for example, a platen shield and a slurry catch (i.e., collection) tray. Embodiments of a slurry catch tray suitable for use with the present inventive concept will be described in further detail below. Various other implementations of the slurry collection mechanism 203 are contemplated and are within the scope of the inventive concept, including the use of vacuum slurry collection techniques, as will become apparent to those skilled in the art given the teachings herein.

Slurry received from the CMP tool 202 using the slurry collection mechanism 203 may be supplied to a slurry diversion mechanism 204. During a first interval of a CMP processing cycle, the slurry diversion mechanism 204 may be configured to provide slurry received from the CMP tool(s) 202 to a slurry recycle vessel(s) 210. The CMP slurry recycling system 200 further includes a slurry redistribution mechanism 218 configured to receive slurry from the slurry recycle vessel(s) 210 and to provide reconditioned (i.e., refreshed) slurry to the CMP tool 202. In some embodiments, the slurry recycle vessel 210 may comprise a plurality of vessels connected in parallel or serially to monitor and/or perform different or progressive reconditioning steps (i.e., processes).

In one or more embodiments, the slurry diversion mechanism 204 may include, for example, a two-way valve 205. The valve 205 may be external to the slurry collection mechanism 203 or it may be integrated within the slurry collection mechanism 203. Optionally, the valve 205 may provide the received slurry, via a first output port thereof, to a first filter 206 during the first interval of the CMP processing cycle and, during a second interval of the CMP processing cycle, the valve 205 may direct the received slurry, via a second output port thereof, to a drain where the slurry is discarded.

The first interval of the CMP processing cycle for a given wafer may be defined as an intermediate stage CMP processing window of the CMP processing cycle during which the slurry is generally not degraded. The second interval of the CMP processing cycle may be defined as an interval(s) of the CMP processing cycle, outside of the first interval, during which there is a higher likelihood of degradation of the slurry. For example, during a final portion of the CMP polishing (e.g., the last minute or so of the CMP processing cycle), the wafer is de-chucked from the CMP tool and the polishing pad is reconditioned, which generally involves the use of cleaning solutions (i.e., cleaning chemistry). During an initial (start-up) portion of the CMP polishing (e.g., the first 30 seconds or so), some cleaning solution may remain on the polishing pad. Slurry collected during this second interval of the CMP processing cycle therefore has a higher likelihood of being degraded by these cleaning solutions.

The first filter 206, when used, may be configured to remove suspended particles greater than a first prescribed size (e.g., about 50-100 μm); the first filter may be considered a coarse filter. Slurry recovered during the first portion of the CMP processing cycle may be provided to the first filter 206 through an optional check valve 208 included in the slurry diversion mechanism 204 and disposed in-line between the first output port of the diverter valve 205 and an input of the first filter 206. The check valve 208 may be a one-way valve configured to prevent back flow of the received slurry to the CMP tool 202 and/or to a drain.

Recovered slurry passing through the first filter 206, which may be referred to herein as coarsely filtered slurry, may be supplied to the slurry recycle vessel 210. The slurry recycle vessel 210 may be configured to at least temporarily hold the received slurry while inline monitoring of one or more properties (e.g., permanganate concentration) of the slurry is performed, for example using an inline slurry monitoring apparatus 212 (such as any of those described above with respect to FIGS. 2-5). For example, a portion of the slurry in the slurry recycle vessel 210 may be diverted to a vessel (e.g., cuvette) for spectrophotometry. In one or more embodiments, the slurry recycle vessel 210 may include a recirculating pump (not explicitly shown) configured to mix the slurry, either continuously or at prescribed intervals, so that the suspended abrasive remains evenly distributed throughout the slurry. Other systems (e.g., a mechanical stirrer) may be used to keep the suspended abrasive evenly distributed throughout the slurry. In some embodiments, a centrifuge is connected to the slurry recycle vessel 210 to remove abrasive particles from a sample diverted to the slurry monitoring apparatus. In some embodiments, an additional dilution line (e.g., DI water line) can be connected to the slurry line diverted to the spectrometer for sample dilution. In some embodiments, the slurry recycle vessel 210 may be implemented as a simple conduit or tube through which the received slurry passes without being stored. In this case, recirculation of the slurry may not be required. In some embodiments, the slurry recycle vessel 210 may include a refrigeration and/or heating unit (not explicitly shown) configured to cool and/or heat the slurry, respectively, for maintaining the slurry at constant temperature (e.g., room temperature) as it is held in the vessel 210.

Measurement data (i.e., inline metrology information) from the inline slurry monitoring apparatus 212 may be used to provide feedback regarding slurry degradation, as discussed above. This information may be supplied to a slurry recycling controller 214 (which may or may not be the same as controller 160 (FIG. 1). The slurry recycling controller 214 may be configured to control one or more functions of the slurry diversion mechanism 204, the slurry redistribution mechanism 218, and/or the CMP tool(s) 202. In some embodiments, the slurry recycling controller 214 is external to the slurry redistribution mechanism 218, while in other embodiments, the slurry recycling controller 214 may be integrated with the slurry redistribution mechanism 218.

The slurry recycling controller 214 (e.g., microprocessor, central processing unit (CPU), etc.) may be configured to receive the metrology information (e.g., absorbance or scattering levels) from the inline monitor 212 and to refresh (i.e., recondition) the slurry in the slurry recycle vessel 210. For example, unused (i.e., fresh) slurry (e.g., potassium permanganate) or a more concentrated solution of the slurry (e.g., potassium permanganate) may be mixed with the slurry held in the slurry recycle vessel 210 when it is determined that the slurry has degraded below a prescribed threshold. In one or more embodiments, fresh slurry and/or a more concentrated slurry used to refresh or recondition the slurry in the slurry recycle vessel 210 may be stored in a reconditioning solution container 216 in operative connection with the slurry recycle vessel 210. The reconditioning solution container 216 may be included as part of the slurry redistribution mechanism 218. Solution(s) stored in the reconditioning solution container 216 may be mixed with the slurry in the slurry recycle vessel 210 for refreshing the slurry therein. The flow of solution(s) from the reconditioning solution container 216 may be controlled by the slurry recycling controller 214.

In one or more embodiments, the slurry recycling controller 214, in conjunction with the inline monitor 212 and the reconditioning solution container 216, may be configured, for example, to raise or lower the pH of the recovered slurry, such as by feeding a base or acid solution, respectively, to the slurry recycle vessel 210 to be mixed with the recycled slurry held in the vessel. Furthermore, the slurry recycling controller 214 may be configured to add buffers to stabilize the pH of the slurry, to add ions for maintaining ionic strength (conductivity) of the slurry, and/or to add stabilizing chemistries to control slurry degradation (e.g., to control degradation of permanganate, add periodate, persulfate, etc.). In other embodiments, the slurry recycling controller 214 may include a mechanism for adding abrasive (e.g., alumina, silica, etc.) to the recovered slurry. Regardless of the mechanism(s) employed, the inline slurry monitoring apparatus 212, the slurry recycling controller 214, and the reconditioning solution container 216 may form a closed loop feedback system with the slurry recycle vessel 210 to control a quality of the recycled slurry (e.g., permanganate concentration) so that the recycled slurry may be restored to an initial state of the slurry for continued CMP processing.

When the quality of the recycled slurry has been restored to a prescribed level based on monitoring data provided by the inline slurry monitoring apparatus 212, the slurry redistribution mechanism 218 may be configured to provide (i.e., direct) the recycled slurry held in the slurry recycle vessel(s) 210 to the CMP tool 202, optionally through a second slurry filter 220, such as by the slurry recycling controller 214 sending a control signal to the slurry redistribution mechanism 218. The second filter 220, when used, may be configured to remove suspended particles in the slurry greater than a second prescribed size (e.g., about 1 μm-5 μm), the second prescribed size being smaller than the first prescribed size associated with the first filter 206. The second filter, which may be considered a fine filter, is configured to allow at least some of the abrasive to remain in the slurry for CMP processing. Recycled slurry passing through the second filter 220, which may be referred to herein as finely filtered slurry, may be supplied to back to the CMP tool 202 for continued CMP processing.

Optionally, the slurry redistribution mechanism 218 may include a pump 219 configured to receive the slurry in the slurry recycle vessel 210 and to provide the refreshed slurry to the CMP tools 202. The pump 219 may be used, for example, when the CMP tool 202 is positioned at a higher level than the slurry recycle vessel 210 such that gravity alone cannot supply the refreshed slurry to the CMP tool 202. Although the pump 219 is shown as being connected between the slurry recycle vessel 210 and the second filter 220, the pump 219 may be disposed at other places inline between the slurry recycle vessel 210 and the CMP tool 202.

In some embodiments, the slurry redistribution mechanism 218 may optionally include a slurry vessel or reservoir 221 connected inline between the slurry recycle vessel 210 and the CMP tool 202. The slurry vessel or reservoir 221 may be used as a secondary storage mechanism to hold refreshed slurry to be provided to the CMP tool 202. This arrangement allows the slurry recycle vessel 210 to continue receiving slurry from the CMP tool 202 to be monitored and reconditioned without interrupting the flow of refreshed slurry back to the CMP tool 202.

If one or more properties of the recovered slurry have degraded to below a prescribed threshold (i.e., beyond what the slurry redistribution mechanism 218 can otherwise restore) based on inline metrology (e.g., spectrophotometry) measurements, the slurry recycling controller 214 may be configured to cause the slurry recycle vessel 210 to discard the recycled slurry being held in the vessel. For example, the slurry recycle vessel 210 may include an opening (e.g., in a floor of the reservoir) with a control valve configured to release the slurry in response to a received control signal from the slurry recycling controller 214, or the slurry recycle vessel 210 may include a pump for transferring the recovered slurry out of the slurry recycle vessel 210 to the drain of the CMP slurry recycling system 200.

In one or more embodiments, the slurry recycle vessel 210 may include an overflow sensor configured to release a prescribed amount of slurry when an amount of the recovered slurry in the slurry recycle vessel 210 reaches or exceeds a prescribed threshold level. In some embodiments, the overflow sensor in the slurry recycle vessel 210 may be configured to send a control signal to the diverter valve 205 for directing the recovered slurry to the drain, rather than allowing the slurry to be provided to the slurry recycle vessel 210. In one or more embodiments, the slurry recycle vessel 210 may be configured to have a double containment tank to catch and recycle any slurry overflow.

Although a single CMP tool 202 is depicted in FIG. 6B, it is to be appreciated that the CMP slurry recycling system 200 may be configured to recycle slurry from a plurality of CMP tools. For example, FIG. 6C is a block diagram depicting at least a portion of an illustrative CMP slurry recycling system 250 configured to collect and recycle slurry from a plurality of CMP tools, according to one or more embodiments of the present inventive concept. Referring to FIG. 6C, the CMP slurry recycling system 250 may be similar to the illustrative CMP slurry recycling system 200 shown in FIG. 6B, except that the diverter valve 205 includes multiple input ports configured to receive slurry from a plurality of CMP tools 202A, 202B and 202C. A first slurry collection mechanism 203A may be operatively coupled to a first CMP tool 202A for conveying slurry from the first CMP tool 202A to the diverter valve 205. A second slurry collection mechanism 203B may be operatively coupled to a second CMP tool 202B for conveying slurry from the second CMP tool 202B to the diverter valve 205. Likewise, a third slurry collection mechanism 203C may be operatively coupled to a third CMP tool 202C for conveying slurry from the third CMP tool 202C to the diverter valve 205. It is to be understood that the inventive concept is not limited to any particular number of CMP tools; that is, more than three CMP tools (e.g., four or more CMP tools) or less than three CMP tools (e.g., two CMP tools) may be used, with the diverter valve 205 appropriately configured to have a number of input ports equal to or exceeding the number of CMP tools used with the CMP slurry recycling system 250.

In one or more embodiments, the diverter valve 205 in the CMP slurry recycling system 250 may be configured to open or close one or more of the input ports coupled to the slurry collection mechanism 203A, 203B, 203C of a respective one of the CMP tools 202A, 202B, 202C as a function of one or more parameters, such as, for example, a window of operation of the CMP tools 202A, 202B, 202C (e.g., whether the CMP tool is operating outside of the steady-state CMP processing window). The one or more parameters may be monitored by the CMP tools themselves, or by an external sensing system configured to monitor such parameter(s).

The CMP slurry recycling system 250 may further include a second diverter valve 224 configured to provide recycled (i.e., refreshed or reconditioned) slurry from the slurry recycle vessel(s) 210 to one or more of the CMP tools 202A, 202B, 202C. In one or more embodiments, the second diverter valve 224 may include an input port for receiving recycled slurry from the slurry recycle vessel 210, and a plurality of output ports for providing the recycled slurry to the plurality of CMP tools 202A, 202B, 202C. The diverter valves 204 and 224 could be a single multi-port valve or multiple individual valves.

In one or more embodiments, the second diverter valve 224 may be controlled by the slurry recycling controller 214 or another control means (e.g., processor, microcontroller, etc.) for automatically distributing the recycled slurry to one or more of the CMP tools 202A, 202B, 202C. In some embodiments, the second diverter valve 224 may be controlled by the respective CMP tools 202A, 202B, 202C. A determination as to which CMP tool(s) to distribute the recycled slurry may be based on one or more prescribed parameters monitored by the slurry recycling controller 214 and/or other monitors/sensors, such as, for example, a slurry consumption rate for each of the CMP tools 202A, 202B, 202C.

In one more embodiments, with reference again to FIG. 6B, the slurry collection mechanism 203 may comprise a slurry collection apparatus (e.g., collection tray) operatively attached to or integrated with the CMP tool 202 and configured to at least temporarily contain collected slurry from a platen shield or similar collection mechanism and direct the collected slurry to the slurry recycling system. In some embodiments, the diverter valve 205 of the slurry recycling system 200, or a portion thereof, may be integrated with the slurry collection apparatus. In one or more embodiments, the slurry collection apparatus may be movably attached to the CMP tool, such as with a slidable or pivotable connection arrangement, to enable the slurry collection apparatus to be manually and/or automatically engaged/disengaged from collecting slurry from the CMP tool as desired. For example, the slurry collection apparatus may be engaged for slurry collection during an intermediate stage CMP processing window, which may exclude an initial start-up period of CMP processing and/or an end cleaning period of the CMP processing, and may be disengaged for slurry collection when the CMP tool is operating outside of the intermediate stage CMP processing window.

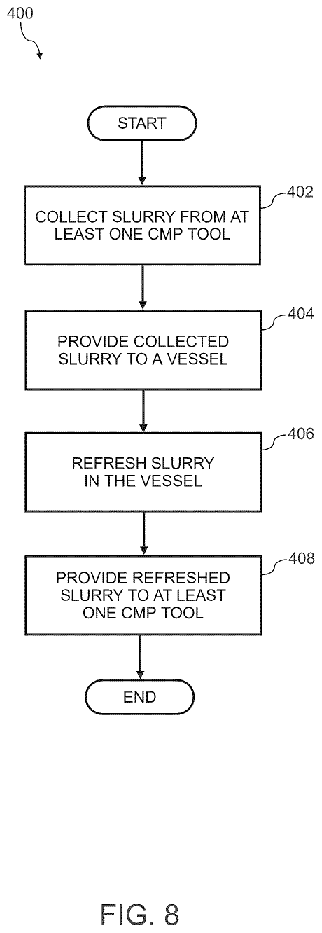

By way of example only and without limitation, FIGS. 7A and 7B depict an example slurry collection apparatus implemented as a slurry collection tray 300 suitable for use with a CMP slurry recycling system (e.g., CMP slurry recycling system 200 shown in FIG. 6B). Referring to FIG. 7A, the slurry collection tray 300 may comprise a floor or base 302, a front wall 304, a back wall 306, and two side walls 308 Each of the front wall 304, the back wall 306 and the side walls 308 may extend vertically upward from the base 302 to define an interior space within the slurry collection tray 300 where collected slurry from the platen of the CMP tool 202 (see FIG. 6B) is received.

In one or more embodiments, the back wall 306 and the front wall 304 may extend longitudinally parallel to one another and intersect the two side walls 308. A longitudinal width of the back wall 306 may be greater than a longitudinal width of the front wall 304, so that the slurry collection tray 300 has a trapezoidal shape when viewed in plan view.

The slurry collection tray 300 may include an opening (i.e., drain) 310 in the base 302 proximate the front wall 304. The opening 310 is configured to allow collected slurry in the slurry collection tray 300 to be provided to the slurry recycle vessel 210 (see FIG. 6B). In one or more embodiments, the base 302 of the slurry collection tray 300 may be inclined downward (i.e., having a negative slope) from the back wall 306 toward the front wall 304 so that the collected slurry flows, by action of gravity, through the opening 310. The base 302 may also be shaped (e.g., V-shaped, curved, etc.) to allow all or most of the collected slurry to flow from the side walls 308 toward the opening 310.

An angle at which the base 302 is tapered is configured to be greater than zero degrees (with zero degrees being horizontal or flat), although embodiments of the inventive concept are not limited to any specific angle of the base 302. In some embodiments, a slope of the base 302 may be configured to control a flow rate of the collected slurry in the slurry collection tray 300. A greater (i.e., steeper) angle of slope of the base 302 enables slurry in the slurry collection tray 300 to be transferred out of the tray more quickly and into the slurry recycle reservoir (e.g., 210 in FIG. 6A), which may reduce the likelihood of contamination of the collected slurry. In some embodiments, the base 302 may be flat, such that the slurry drains through the opening 310 once a level of the slurry in the slurry collection tray 300 has reached a prescribed height. In some embodiments, one or more of the sidewalls 308 of the slurry collection tray 300 may be angled (i.e., inclined or sloped) inwardly to allow collected slurry on the sidewalls 308 to be directed toward the opening 310 in the base 302 for providing the collected slurry to the slurry recycling system 200 (see FIG. 6B).

In one or more embodiments, the front wall 304 may optionally include a cutout 312. The cutout 312 may be semi-circular in shape, extending partially downward from a top edge of the front wall 304, although embodiments are not limited thereto. The cutout 312 is configured to provide a means of grasping the slurry collection tray 300 for sliding the tray (e.g., backwards or forwards) when manually repositioning the slurry collection tray 300 to avoid collecting slurry during intervals of the CMP processing cycle in which contamination is more likely (e.g., initial start-up period and/or end cleaning period). In one or more embodiments, the slurry collection tray 300 may include an attachment structure 314, which may be configured as a hollow cylindrical structure affixed to one of the sidewalls 308 of the slurry collection tray 300. The attachment structure 314 may be adapted to receive a pin or rod for pivotal attachment to the CMP tool. This attachment arrangement may facilitate manual and/or automatic engagement/disengagement of the slurry collection tray 300 with the CMP tool.

Referring now to FIG. 7B, in some embodiments, the slurry collection tray 300 may optionally include a cover 320 provided over at least a portion of the slurry collection tray 300. The cover 320 may be supported by an upper rim 322 of the slurry collection tray 300 defined by a top edge of each of the front wall 304, the back wall 306 and/or the two side walls 308. The cover 320 may further reduce the likelihood of contaminants being introduced into the collected slurry.

In one or more embodiments, a suction (i.e., vacuum) system may be used in place of or in addition to the slurry collection tray 300. For example, when using the slurry collection tray 300, rather than relying on gravity for transferring the collected slurry to the diverter valve (e.g., 205 in FIG. 6B), the opening 310 in the base 302 of the slurry collection tray 300 may be omitted and a vacuum line (not explicitly shown, but implied) may be provided proximate the base 302 of the slurry collection tray 300 and coupled with the diverter valve 205 (see FIG. 6B) for providing collected slurry from the slurry collection tray 300 to the slurry recycle vessel 210 of the slurry recycling system 200 (see FIG. 6B).

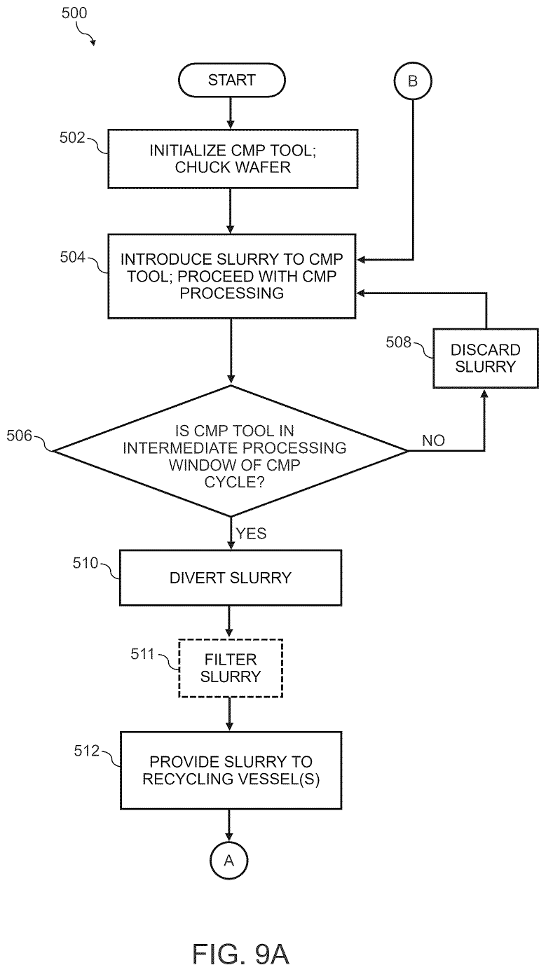

FIG. 8 depicts a flow chart of an example method 400 according to example embodiments of the present disclosure. The method 400 may be implemented, for instance, using a slurry recycling system, such as any of those shown in FIGS. 6A-6C. The method 400 depicts operations performed in a particular order for purposes of illustration and discussion. Those of ordinary skill in the art, using the disclosures provided herein, will understand that the operations of any of the methods described herein may be adapted, expanded, performed simultaneously, omitted, rearranged, include steps not illustrated, and/or modified in various ways without deviating from the scope of the present disclosure.

At 402, the method 400 includes collecting slurry from at least one CMP tool. At 404, the method 400 includes providing the collected slurry to a vessel (e.g., the slurry recycle vessel(s) 210 in FIGS. 6B and 6C). As described in connection with FIG. 6B, the slurry may be collected in an intermediate stage CMP processing window of a CMP processing cycle during which the slurry has a lower likelihood of being diluted and/or contaminated, for example by cleaning chemistry.

At 406, the method 400 includes refreshing (i.e., reconditioning) the received slurry in the vessel. Specifically, one or more properties (e.g., permanganate concentration and/or MnO₂ formation) of the slurry in the vessel may be monitored and, when at least one property being monitored is outside of a prescribed threshold or range, certain actions may be taken to refresh the slurry. Refreshing the slurry may involve, for example, adding fresh slurry or a concentrated solution to the slurry in the vessel. At 408, the method 400 includes providing the refreshed slurry to the CMP tool.

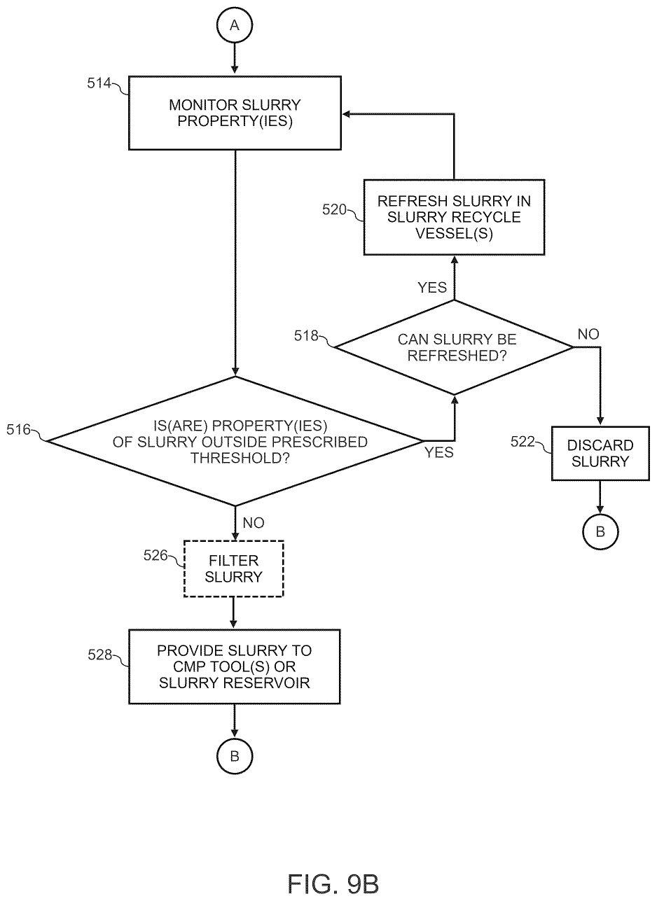

FIGS. 9A and 9B depict flow charts of an example method 500 according to example embodiments of the present disclosure. The method 500 may be implemented, for instance, using a slurry recycling system, such as any of those shown in FIGS. 6A-6C. The method 500 depicts operations performed in a particular order for purposes of illustration and discussion. Those of ordinary skill in the art, using the disclosures provided herein, will understand that the operations of any of the methods described herein may be adapted, expanded, performed simultaneously, omitted, rearranged, include steps not illustrated, and/or modified in various ways without deviating from the scope of the present disclosure.

At 502, the method 500 includes initializing the CMP tool. Initialization may involve, for example, providing a polishing pad on the platen of the CMP tool and chucking the wafer on a carrier to begin a CMP processing cycle. At 504, slurry is introduced to the CMP tool and CMP processing proceeds. During this initial stage in the CMP processing, before intermediate stage CMP processing has begun, the method is configured to prevent collection of slurry.

Slurry collected during certain stages of the CMP processing cycle will have a higher likelihood of being contaminated, such as by cleaning solutions (i.e., cleaning chemistry). As previously explained, it is preferable to avoid slurry collection during an initial start-up period (e.g., the first 30 seconds or so) of the CMP processing cycle where there is a likelihood that cleaning materials may be present after processing a prior wafer, and during an end period during which the polishing pad is being cleaned and reconditioned (e.g., the last minute or so of the CMP processing cycle). There is a lower likelihood of slurry dilution and/or contamination during this intermediate stage CMP processing window, where CMP polishing has already started and before the wafer has been de-chucked from the CMP tool and pad cleaning has begun.

At 506, the method 500 includes determining whether the CMP tool is in the intermediate stage CMP processing window of the CMP processing cycle. When it is determined that the CMP processing cycle is outside of the intermediate stage CMP processing window, the method 500 includes discarding collected slurry at 508, such as by directing the slurry to a drain of the CMP tool, or otherwise preventing the CMP tool from collecting slurry. When it is determined in step 506 that the CMP tool is within the intermediate stage CMP processing window, the method 500 includes diverting the collected slurry at 510 (e.g., using the slurry diversion mechanism 204 shown in FIG. 6B). Optionally, the method 500 may include filtering the slurry at 511, such as by providing the slurry to a first filter (e.g., first filter 206 in FIG. 6B). The first filter may be configured to remove, for example, large suspended particles and/or agglomerates, polishing pad debris, and CMP by-products in the slurry that are greater than a first prescribed size (e.g., about 50-100 μm). Particles of this first prescribed size may be considered coarse particles, larger than a size of the abrasive contained in fresh (i.e., unused) slurry.

At 512, the method 500 may include providing the slurry diverted at 510 to a slurry recycle vessel or reservoir (e.g., slurry recycle vessel 210 in FIG. 6B). The received slurry may be held in the vessel until it is determined that it is ready to be introduced back to the CMP tool. In some embodiments, the slurry recycle vessel may be configured to recirculate or mix the slurry so that the abrasive remains suspended in solution. At 514, one or more properties of the slurry are examined, for example using inline spectrophotometry (e.g., inline monitoring apparatus 212 in FIG. 6B or the apparatuses described with respect to FIGS. 2-5) configured to measure the concentration of permanganate compounds and/or MnO₂ in the slurry.

At 516, the method 500 may include determining whether or not the property(ies) being monitored are outside of a prescribed threshold or range. For example, a slurry monitoring apparatus may determine whether a permanganate concentration is above a threshold limit. At 518, the method 500 can include determining whether the slurry can be refreshed to its original condition when the property(ies) of the slurry being monitored falls outside of the prescribed threshold or range.

At 520, the method 500 may include taking certain actions to refresh the slurry if it is determined at 518 that the slurry can be refreshed. Such actions may include, but are not limited to, adding fresh slurry or a concentrated solution to the slurry recycle vessel. The method 500 then returns to 514 where one or more parameters of the slurry are monitored to determine whether the condition of the refreshed slurry has improved. At 522, the method 500 may include discarding the slurry if it is determined in step 518 that the slurry cannot be refreshed (e.g., permanganate in the slurry has been fully consumed). At that point, fresh slurry is introduced to the CMP tool at 524 and the CMP processing cycle continues until the wafer has completed CMP.

At 526, the method may include filtering the slurry when it is determined at 516 that the property(ies) of the slurry being monitored has not exceeded the prescribed threshold or range. Filtering may include providing the slurry to a second filter (e.g., second filter 220 in FIG. 6B). The second filter may be configured to remove suspended particles in the collected slurry that are greater than a second prescribed size (e.g., about 1 μm-5 μm). Particles of this second prescribed size may be considered fine particles, smaller in size than particles remaining in the slurry after passing through the first filtering at 510. At 528, method 500 may include providing the recycled (i.e., refreshed) slurry to the CMP tool after it passes through the second filter or if filtering is not performed, and CMP processing continues until the wafer has completed CMP. In this manner, the slurry recycling method 500 maintains the quality of the recycled slurry at or near the quality of fresh (i.e., unused) slurry thereby saving significant cost in CMP processing, particularly for single-wafer CMP tools adapted to process 150 mm or greater SiC wafers.

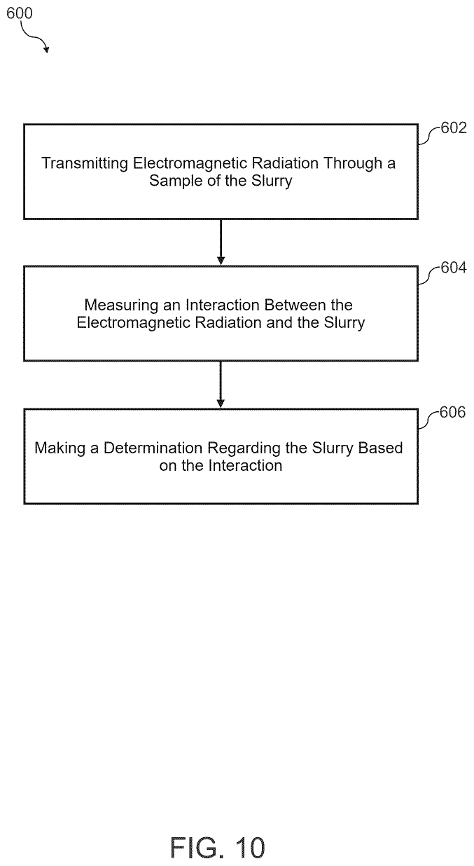

FIG. 10 depicts a flow chart of an example method 600 according to example embodiments of the present disclosure. The method 600 may be implemented, for instance, using a slurry monitoring apparatus, such as any of those shown in FIGS. 2-5. The method 600 depicts operations performed in a particular order for purposes of illustration and discussion. Those of ordinary skill in the art, using the disclosures provided herein, will understand that the operations of any of the methods described herein may be adapted, expanded, performed simultaneously, omitted, rearranged, include steps not illustrated, and/or modified in various ways without deviating from the scope of the present disclosure.

At 602, the method 600 may include transmitting electromagnetic radiation through a sample of a slurry. For example, a monochromatic beam of radiation can be directed toward a vessel containing a sample of the slurry. In some embodiments, the electromagnetic radiation may be transmitted by an LED light source, such as a GaN/SiC, GaN/Sapphire, InGaN/Sapphire or GaP/GaP LED light source. The electromagnetic radiation may be transmitted through one or more focusing elements and/or spectral filters to produce a beam of monochromatic light directed at the sample.

The specific wavelength may be any that may interact with a species in the slurry, particularly in a manner in which the level of interaction (e.g., absorbance or scattering) is correlated with the concentration of that species in the slurry. For example, when examining the slurry for the concentration of a permanganate compound, the specific wavelength may be in the visible light spectrum, and more particularly in the range from about 500 nm to about 570 nm, at which permanganate compounds typically have absorption peaks. In some embodiments, a component of the slurry, such as a solid particle species (e.g., MnO₂), scatters at least a portion of the electromagnetic radiation at the specific wavelength.

The slurry sample may include a solvent or carrier (e.g., water), an oxidizing agent, and optionally abrasive particles. In some embodiments, particularly when the semiconductor workpiece is a silicon carbide workpiece, the oxidizing agent contains permanganate ions, such as those from sodium permanganate and potassium permanganate. The slurry may also contain degradation products, such as MnO₂ formed from the degradation of permanganate oxidizers.

For slurries containing abrasive particles, the method 600 may also include removing the abrasive particles from the slurry prior to testing. Removal may include a filtering or centrifugation process. For example, the slurry can be separated by a centrifuge and the supernatant can be used as the slurry sample for examination.

At 604, the method 600 may include measuring an interaction between the electromagnetic radiation and the slurry. The interaction can include absorbance by a compound (e.g., a permanganate) that absorbs electromagnetic radiation at the specific wavelength (e.g., in the range of 500 nm to 570 nm) or scattering by suspended solids (e.g., MnO₂).

Measuring can be done by a detector which measures the intensity of the electromagnetic radiation that passes through the slurry sample or that is deflected by the slurry sample. For example, in the case of an LED light source, the detector may include one or more light sensitive diodes, which produce an electrical signal proportional to the intensity of the light emitted. Absorbance can be determined from the difference between the strength of the light transmitted to the sample to the strength of the light detected after passing through the sample. Scattering can be determined by the intensity of light that is deflected at an angle relative to the initial light path.

At 606, the method 600 may include making a determination regarding the slurry based on the interaction. The determination may include a determination of the concentration of a component, such as a permanganate compound (e.g., potassium permanganate or sodium permanganate) or a degradation product (e.g., MnO₂). Such concentrations may be determined from the measurement of absorbance and/or scattering. For example, a calibration curve of light absorbance vs permanganate concentration can be made by measuring the absorbance of two or more standard slurries (i.e., slurries with known permanganate concentrations) and an unknown concentration can be determined by measuring the absorbance and using the calibration curve to determine the corresponding permanganate concentration.

In other embodiments, a calibration curve of light scattering vs MnO₂ concentration can be created by measuring the scattering of two or more standard slurries (i.e., slurries with known MnO₂ concentrations) and an unknown MnO₂ concentration can be determined by measuring the scattering and using the calibration curve to determine the corresponding MnO₂ concentration.

In some embodiments, the electromagnetic radiation comprises at least a first specific wavelength (e.g., 500 to 570 nm) and a second specific wavelength (e.g., visible light outside of the 500 to 570 nm range). One component of the slurry (e.g., a permanganate) can absorb at least a portion of the electromagnetic radiation at the first specific wavelength and a second component of the slurry (e.g., MnO₂) can scatter at least a portion of the electromagnetic radiation at the second specific wavelength. A concentration of the first component can be determined from the absorbance of the electromagnetic radiation at the first wavelength and a concentration of the second component can be determined based on the scattering of the electromagnetic radiation at the second wavelength.

Method 600 may be performed using a spectrophotometer, such as a fiber spectrometer or a micro spectrometer. In some embodiments, the method may include measuring both transmitted and reflected light, for example, by using an integrating sphere, goniometer, or movable mirror arrangement. The method may also be performed as a part of another optical metrology system, such as dynamic light scattering, FTIR, Raman, large spectrum analysis, scatterometry, or a camera system.

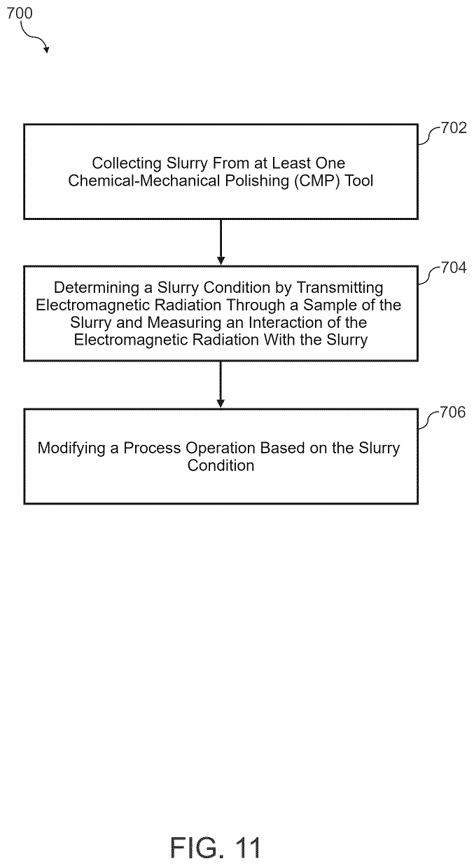

FIG. 11 depicts a flow chart of an example method 700 according to example embodiments of the present disclosure. The method 700 may be implemented, for instance, using a slurry monitoring apparatus, such as any of those shown in FIGS. 2-5 as part of a slurry recycling system, such as those described in FIGS. 6A-6C. The method 700 depicts operations performed in a particular order for purposes of illustration and discussion. Those of ordinary skill in the art, using the disclosures provided herein, will understand that the operations of any of the methods described herein may be adapted, expanded, performed simultaneously, omitted, rearranged, include steps not illustrated, and/or modified in various ways without deviating from the scope of the present disclosure.

At 702, the method 700 may include collecting slurry from at least one CMP tool (e.g., a silicon carbide CMP tool). Collating may be performed by a slurry collection tray operatively attached to or integrated with the CMP tool and configured to at least temporarily contain collected slurry from a platen shield or similar collection mechanism, as described above.

At 704, the method 700 may include determining a slurry condition by transmitting electromagnetic radiation through a sample of the slurry and measuring an interaction of the electromagnetic radiation with the slurry. The transmitting, measuring, and determining operations can be performed as described above for method 600 with respect to FIG. 10.

At 706, the method 700 may include modifying a process operation based on the slurry condition. Modifying the process operation includes determining if the slurry is suitable for recycling, refreshing the slurry if needed, and providing the collected or refreshed slurry to the at least one CMP tool.

Determining whether the slurry is suitable for recycling can be performed by comparing the slurry condition to a threshold. For example, if a permanganate concentration is within a prescribed threshold range, the slurry can be considered suitable for recycling and if the permanganate concentration is outside the prescribed threshold range, the slurry can be determined to need discarding or refreshing. Similarly, rather than having a prescribed permanganate concentration range, the range can simply be based on the absorbance value (i.e., a prescribed absorbance threshold), as the two are correlated. The threshold can also be based on a concentration of MnO₂. For example, if the concentration of MnO₂ is below a prescribed threshold, the slurry can be considered suitable for recycling. If it is above the prescribed threshold, it can be determined to need discarding or refreshing. Similarly, the scattering level over time can be tracked by measuring a series of slurry samples collected at different times, and a threshold for the change in scattering level compared to a baseline level (i.e., that of a nondegraded slurry) can be set. When the change in scattering level exceeds that threshold, the slurry can be considered to need discarding or refreshing.

If it is determined that refreshing is needed, refreshing can include additive reconditioning or subtractive reconditioning. Additive reconditioning may include adding a permanganate solution (e.g., a solution having a higher concentration of permanganate than the level desired in the slurry) to the slurry. In some embodiments, for example, the permanganate solution can include potassium permanganate. Subtractive reconditioning may include removing particles, such as MnO₂ particles above a prescribed size threshold (e.g., by filtering with a filter designed to remove particles having a size above the threshold). After refreshing the slurry by additive or subtractive reconditioning, the slurry can be provided back to the CMP tool. Such operations are described in detail with respect to methods 400 and 500 described above with respect to FIGS. 8, 9A, and 9B.

Example aspects of the present disclosure are set forth below. Any of the below features or examples may be used in combination with any of the embodiments or features provided in the present disclosure.

In an aspect, the present disclosure provides an example method for examining a chemical mechanical polishing (CMP) slurry. The method comprises transmitting electromagnetic radiation through a sample of the slurry, measuring an interaction between the electromagnetic radiation and the slurry, and making a determination regarding the slurry based on the interaction. The slurry interacts with at least a portion of electromagnetic radiation.

In some implementations of the example method, the electromagnetic radiation comprises at least one specific wavelength.

In some implementations of the example method, a component of the slurry absorbs at least a portion of the electromagnetic radiation at the specific wavelength.

In some implementations of the example method, the interaction is absorbance of the electromagnetic radiation at the specific wavelength.

In some implementations of the example method, making the determination comprises determining a concentration of the component in the slurry.

In some implementations of the example method, the component is a permanganate compound.

In some implementations of the example method, the permanganate compound is potassium permanganate.

In some implementations of the example method, the permanganate compound is sodium permanganate.

In some implementations of the example method, the specific wavelength is within the visible light spectrum.

In some implementations of the example method, the specific wavelength is in the range of about 500 nm to about 570 nm.

In some implementations of the example method, a component of the slurry scatters at least a portion of the electromagnetic radiation at the specific wavelength.

In some implementations of the example method, the interaction is scattering of the electromagnetic radiation at the specific wavelength.

In some implementations of the example method, making the determination comprises determining a concentration of the component in the slurry.

In some implementations of the example method, the component is a solid particle species.

In some implementations of the example method, the solid particle species is manganese dioxide.

In some implementations of the example method, determining the concentration of the component comprises comparing the measured scattering to a calibration curve of scattering created for the CMP slurry.

In some implementations of the example method, determining the concentration of the component comprises comparing the measured absorbance to a calibration curve of absorbance created for the CMP slurry.

In some implementations of the example method, the slurry comprises abrasive particles.

In some implementations, the example method further comprises separating the abrasive particles from an abrasive free sample of the slurry and measuring the interaction using the abrasive free sample.

In some implementations of the example method, separating comprises centrifuging.

In some implementations of the example method, the slurry does not comprise abrasive particles.

In some implementations of the example method, the method is performed using a spectrometer.

In some implementations of the example method, the spectrometer comprises a fiber spectrometer or a micro spectrometer.

In some implementations of the example method, the electromagnetic radiation is transmitted by an LED light source.

In some implementations of the example method, the absorbance is measured using one or more light sensitive diodes.

In some implementations of the example method, the electromagnetic radiation of the specific wavelength is generated using one or more spectral filters.

In some implementations of the example method, the absorption is measured by capturing transmitted and reflected light.

In some implementations of the example method, an integrating sphere, goniometer, or movable mirror arrangement is used to capture at least a portion of the transmitted and reflected light.

In some implementations of the example method, the absorbance is measured as a part of an optical metrology system comprising dynamic light scattering, FTIR, Raman, large spectrum analysis, scatterometry, or a camera system.

In some implementations of the example method, the electromagnetic radiation comprises at least a first specific wavelength and a second specific wavelength, wherein a first component of the slurry absorbs at least a portion of the electromagnetic radiation at the first specific wavelength, wherein a second component of the slurry scatters at least a portion of the electromagnetic radiation at the second specific wavelength, wherein the interaction comprises absorbance of the electromagnetic radiation at the first specific wavelength and scattering of the electromagnetic radiation at the second specific wavelength, and wherein making the determination comprises determining a concentration of the first component in the slurry based on the absorbance of the electromagnetic radiation at the first specific wavelength and determining a concentration of the second component in the slurry based on the scattering of the electromagnetic radiation at the second specific wavelength.

In some implementations of the example method, the slurry is a silicon carbide (SiC) CMP slurry.

In another aspect, the present disclosure provides an example slurry recycling system. The system comprises a slurry diversion system configured to receive slurry from at least one chemical-mechanical polishing (CMP) tool; a vessel configured to receive slurry diverted from the at least one CMP tool for reconditioning of the slurry; a slurry monitoring system configured to transmit electromagnetic radiation through a sample of the slurry, measure an interaction of the electromagnetic radiation with the slurry, and determine if the slurry is suitable for recycling; and a slurry redistribution system to provide reconditioned slurry to the at least one CMP tool.

In some implementations of the example slurry recycling system, the slurry redistribution system is further configured to refresh the slurry when the slurry monitoring system determines that the slurry is not suitable for recycling.

In some implementations of the example slurry recycling system, the slurry redistribution system is configured to refresh the slurry by performing additive reconditioning of the slurry in the vessel.

In some implementations of the example slurry recycling system, additive reconditioning comprises adding a solution to the slurry.

In some implementations of the example slurry recycling system, the solution comprises a permanganate compound.

In some implementations of the example slurry recycling system, the permanganate compound comprises potassium permanganate.

In some implementations of the example slurry recycling system, the slurry redistribution system is configured to refresh the slurry by performing subtractive reconditioning of the slurry in the vessel.

In some implementations of the example slurry recycling system, subtractive reconditioning comprises removing suspended particles in the slurry greater than a prescribed size.

In some implementations of the example slurry recycling system, the suspended particles comprise manganese dioxide.

In some implementations of the example slurry recycling system, the interaction comprises absorbance of a specific wavelength of the electromagnetic radiation by the slurry.

In some implementations of the example slurry recycling system, the slurry monitoring system is configured to determine the concentration of a component of the slurry based on the absorbance measured, wherein the component absorbs electromagnetic radiation at the specific wavelength.

In some implementations of the example slurry recycling system, the slurry monitoring system is configured to determine the concentration of the component by comparing the measured absorbance to a calibration curve of absorbance created for the CMP slurry.

In some implementations of the example slurry recycling system, the component is a permanganate compound.

In some implementations of the example slurry recycling system, the permanganate compound is potassium permanganate.

In some implementations of the example slurry recycling system, the compound is sodium permanganate.

In some implementations of the example slurry recycling system, the specific wavelength is within the visible light spectrum.

In some implementations of the example slurry recycling system, the specific wavelength is in the range of 500 nm to 570 nm.

In some implementations of the example slurry recycling system, the interaction comprises scattering of a specific wavelength of the electromagnetic radiation.

In some implementations of the example slurry recycling system, the slurry monitoring system is configured to determine the concentration of a solid particle species in the slurry based on the scattering measured.

In some implementations of the example slurry recycling system, the solid particle species is manganese dioxide.

In some implementations of the example slurry recycling system, the slurry monitoring system is configured to determine the concentration of the solid particle species by comparing the measured scattering to a calibration curve of scattering created for the CMP slurry.

In some implementations of the example slurry recycling system, the slurry comprises abrasive particles.

In some implementations of the example slurry recycling system, the slurry monitoring system is configured to separate the abrasive particles from an abrasive free sample of the slurry and to measure the absorbance and/or scattering in the abrasive free sample.

In some implementations of the example slurry recycling system, the slurry monitoring system is configured to separate the abrasive particles from the abrasive free sample by centrifuging.

In some implementations of the example slurry recycling system, the slurry does not comprise abrasive particles.

In some implementations of the example slurry recycling system, the slurry monitoring system comprises a spectrometer.

In some implementations of the example slurry recycling system, the spectrometer comprises a fiber spectrometer or a micro spectrometer.

In some implementations of the example slurry recycling system, the slurry monitoring system comprises an LED light source.

In some implementations of the example slurry recycling system, the slurry monitoring system comprises one or more light sensitive diodes.

In some implementations of the example slurry recycling system, the slurry monitoring system comprises one or more spectral filters.

In some implementations of the example slurry recycling system, the slurry monitoring system is configured to measure transmitted and reflected light.

In some implementations of the example slurry recycling system, the slurry monitoring system comprises an integrating sphere, goniometer, or movable mirror arrangement.

In some implementations of the example slurry recycling system, the slurry monitoring system is configured to determine if the slurry is suitable for recycling by comparing a concentration of a component to a prescribed threshold concentration.

In some implementations of the example slurry recycling system, the component is a permanganate compound.

In some implementations of the example slurry recycling system, the component is manganese dioxide.

In some implementations of the example slurry recycling system, the interaction comprises absorbance of a specific wavelength of the electromagnetic radiation and the slurry monitoring system is configured to determine if the slurry is suitable for recycling by comparing absorbance to a prescribed threshold absorbance range.

In some implementations of the example slurry recycling system, the interaction comprises scattering of a specific wavelength of the electromagnetic radiation and the slurry monitoring system is configured to determine if the slurry is suitable for recycling by comparing scattering to a prescribed threshold scattering range.

In some implementations of the example slurry recycling system, the interaction comprises scattering of a specific wavelength of the electromagnetic radiation and the slurry monitoring system is configured to determine if the slurry is suitable for recycling by comparing measured scattering level to a baseline scattering level and determining whether a difference from the measured scattering level to the baseline scattering level is within a prescribed threshold.

In some implementations of the example slurry recycling system, the at least one CMP tool is a silicon carbide (SiC) CMP tool.

In some implementations of the example slurry recycling system, the slurry monitoring system is configured to transmit electromagnetic radiation of a first wavelength and a second wavelength and the interaction comprises the absorbance of the electromagnetic radiation at the first wavelength and the scattering of the electromagnetic radiation at the second wavelength.

In another aspect, the present disclosure provides an example slurry monitoring apparatus. The apparatus is configured to transmit electromagnetic radiation of a specific wavelength through a sample of a chemical mechanical polishing (CMP) slurry, measure absorbance of the electromagnetic radiation by the slurry, and determine if the slurry is suitable for use.

In some implementations of the example slurry monitoring apparatus, the apparatus is configured to determine the concentration of a component of the slurry based on the absorbance measured, wherein the component absorbs electromagnetic radiation at the specific wavelength.

In some implementations of the example slurry monitoring apparatus, the apparatus is configured to determine the concentration of the component by comparing the measured absorbance to a calibration curve of absorbance created for the CMP slurry.

In some implementations of the example slurry monitoring apparatus, the component is a permanganate compound.

In some implementations of the example slurry monitoring apparatus, the permanganate compound is potassium permanganate.

In some implementations of the example slurry monitoring apparatus, the compound is sodium permanganate.

In some implementations of the example slurry monitoring apparatus, the specific wavelength is within the visible light spectrum.

In some implementations of the example slurry monitoring apparatus, the specific wavelength is in the range of 500 nm to 570 nm.

In some implementations of the example slurry monitoring apparatus, the apparatus is further configured to measure scattering of the electromagnetic radiation.

In some implementations of the example slurry monitoring apparatus, the apparatus is configured to determine the concentration of a solid particle species in the slurry based on the scattering measured.

In some implementations of the example slurry monitoring apparatus, the solid particle species is manganese dioxide.

In some implementations of the example slurry monitoring apparatus, the slurry monitoring system is configured to determine the concentration of the solid particle species by comparing the measured scattering to a calibration curve of scattering created for the CMP slurry.

In some implementations of the example slurry monitoring apparatus, the slurry comprises abrasive particles.

In some implementations of the example slurry monitoring apparatus, the slurry monitoring apparatus is further configured to separate the abrasive particles from an abrasive free sample of the slurry and to measure the absorbance of the abrasive free sample.

In some implementations of the example slurry monitoring apparatus, the slurry monitoring apparatus is configured to separate the abrasive particles from the abrasive free sample by centrifuging.

In some implementations of the example slurry monitoring apparatus, the slurry does not comprise abrasive particles.

In some implementations of the example slurry monitoring apparatus, the slurry monitoring apparatus comprises a spectrometer.

In some implementations of the example slurry monitoring apparatus, the spectrometer comprises a fiber spectrometer or a micro spectrometer.

In some implementations of the example slurry monitoring apparatus, the slurry monitoring apparatus comprises an LED light source.

In some implementations of the example slurry monitoring apparatus, the slurry monitoring apparatus comprises one or more light sensitive diodes.

In some implementations of the example slurry monitoring apparatus, the slurry monitoring apparatus comprises one or more spectral filters.

In some implementations of the example slurry monitoring apparatus, the slurry monitoring apparatus is configured to measure transmitted and reflected light.

In some implementations of the example slurry monitoring apparatus, the slurry monitoring apparatus comprises an integrating sphere, goniometer, or movable mirror arrangement.

In some implementations of the example slurry monitoring apparatus, the slurry monitoring apparatus is configured to determine if the slurry is suitable for use by comparing a concentration of a component to a prescribed threshold concentration.

In some implementations of the example slurry monitoring apparatus, the component is a permanganate compound.

In some implementations of the example slurry monitoring apparatus, the component is manganese dioxide.

In some implementations of the example slurry monitoring apparatus, the slurry monitoring apparatus is configured to determine if the slurry is suitable for use by comparing absorbance to a prescribed threshold absorbance range.

In some implementations of the example slurry monitoring apparatus, the slurry monitoring apparatus is configured to determine if the slurry is suitable for use by comparing scattering to a prescribed threshold scattering range.

In some implementations of the example slurry monitoring apparatus, the slurry monitoring apparatus is configured to determine if the slurry is suitable for use by comparing measured scattering level to a baseline scattering level and determining whether a difference from the measured scattering level to the baseline scattering level is within a prescribed threshold.

In some implementations of the example slurry monitoring apparatus, the slurry monitoring apparatus is configured to transmit electromagnetic radiation of a first wavelength and a second wavelength and is configured to measure the absorbance of the electromagnetic radiation at the first wavelength and the scattering of the electromagnetic radiation at the second wavelength.

In some implementations of the example slurry monitoring apparatus, the slurry is a silicon carbide (SiC) CMP slurry.

In another aspect, the present disclosure provides an example method for recycling slurry. The method comprises collecting slurry from at least one chemical-mechanical polishing (CMP) tool, determining a slurry condition by transmitting electromagnetic radiation through a sample of the slurry and measuring an interaction of the electromagnetic radiation with the slurry, and modifying a process operation based on the slurry condition. Modifying the process operation comprises determining if the slurry is suitable for recycling, refreshing the slurry if needed, and providing the collected or refreshed slurry to the at least one CMP tool.

In some implementations of the example method, refreshing the slurry comprises performing additive reconditioning of the slurry.

In some implementations of the example method, additive reconditioning comprises adding a solution to the slurry.

In some implementations of the example method, the solution comprises a permanganate compound.

In some implementations of the example method, the permanganate compound comprises potassium permanganate.

In some implementations of the example method, refreshing the slurry comprises performing subtractive reconditioning of the slurry in the vessel.

In some implementations of the example method, subtractive reconditioning comprises removing suspended particles in the slurry greater than a prescribed size.

In some implementations of the example method, the suspended particles comprise manganese dioxide.

In some implementations of the example method, the interaction comprises absorbance of a specific wavelength of the electromagnetic radiation by the slurry.

In some implementations, the example method further comprises determining the concentration of a component of the slurry based on the absorbance measured, wherein the component absorbs electromagnetic radiation at the specific wavelength.

In some implementations of the example method, determining the concentration of the component comprises comparing the measured absorbance to a calibration curve of absorbance created for the CMP slurry.

In some implementations of the example method, the component is a permanganate compound.

In some implementations of the example method, the permanganate compound is potassium permanganate.

In some implementations of the example method, the compound is sodium permanganate.

In some implementations of the example method, the specific wavelength is within the visible light spectrum.

In some implementations of the example method, the specific wavelength is in the range of 500 nm to 570 nm.

In some implementations of the example method, the interaction comprises scattering of a specific wavelength of the electromagnetic radiation.

In some implementations, the example method further comprises determining the concentration of a solid particle species in the slurry based on the scattering measured.

In some implementations of the example method, the solid particle species is manganese dioxide.

In some implementations of the example method, determining the concentration of the solid particle species comprises comparing the measured scattering to a calibration curve of scattering created for the CMP slurry.

In some implementations of the example method, the slurry comprises abrasive particles.

In some implementations, the example method further comprises separating the abrasive particles from an abrasive free sample of the slurry and measuring the interaction using the abrasive free sample.

In some implementations of the example method, separating comprises centrifuging.

In some implementations of the example method, the slurry does not comprise abrasive particles.

In some implementations of the example method, measuring the interaction is performed using a spectrometer.

In some implementations of the example method, the spectrometer comprises a fiber spectrometer or a micro spectrometer.

In some implementations of the example method, the electromagnetic radiation is transmitted by an LED light source.

In some implementations of the example method, the interaction is measured using one or more light sensitive diodes.

In some implementations of the example method, the electromagnetic radiation has a specific wavelength generated using one or more spectral filters.

In some implementations of the example method, the interaction is measured by capturing transmitted and reflected light.

In some implementations of the example method, an integrating sphere, goniometer, or movable mirror arrangement is used to capture the transmitted and reflected light.

In some implementations of the example method, determining if the slurry is suitable for recycling comprises comparing a concentration of a component to a prescribed threshold concentration.

In some implementations of the example method, the component is a permanganate compound.

In some implementations of the example method, the component is manganese dioxide.

In some implementations of the example method, the interaction comprises absorbance of a specific wavelength of the electromagnetic radiation and determining if the slurry is suitable for recycling comprises comparing absorbance to a prescribed threshold absorbance range.

In some implementations of the example method, the interaction comprises scattering of a specific wavelength of the electromagnetic radiation and determining if the slurry is suitable for recycling comprises comparing scattering to a prescribed threshold scattering range.

In some implementations of the example method, the interaction comprises absorbance of a specific wavelength of the electromagnetic radiation and determining if the slurry is suitable for recycling comprises comparing measured scattering level to a baseline scattering level and determining whether a difference from the measured scattering level to the baseline scattering level is within a prescribed threshold.

In some implementations of the example method, the at least one CMP tool is a silicon carbide (SiC) CMP tool.

In some implementations of the example method, the electromagnetic radiation comprises a first specific wavelength and a second specific wavelength and the interaction comprises the absorbance of the electromagnetic radiation at the first specific wavelength and the scattering of the electromagnetic radiation at the second wavelength.

In another aspect, the present disclosure provides an example method for determining the shelf life of a CMP slurry containing a permanganate compound. The method comprises periodically measuring the permanganate concentration of the slurry until it falls beneath a threshold concentration corresponding to a minimum useful permanganate concentration and determining the shelf life based on the time elapsed from the manufacturing of the slurry until the permanganate concentration reached the threshold concentration. Each periodic measurement comprises transmitting electromagnetic radiation through a sample of the slurry, measuring an interaction between the electromagnetic radiation and the slurry, and determining the permanganate concentration based on the interaction. The slurry interacts with at least a portion of electromagnetic radiation.

In another aspect, the present disclosure provides an example method of quality control for a silicon carbide wafer manufacturing facility. The method comprises determining whether to use, discard, manufacture, or order CMP slurries based on the shelf life of the CMP slurry determined by the method for determining the shelf life of a CMP slurry containing a permanganate compound.

In another aspect, the present disclosure provides an example predictive project management or factory automation process for a silicon carbide wafer manufacturing facility. The process comprises providing throughput, utilization, or material consumption data of a CMP slurry containing a permanganate compound and examining the CMP slurry by transmitting electromagnetic radiation through a sample of the slurry, measuring an interaction between the electromagnetic radiation and the slurry, and determining the permanganate concentration based on the interaction. The slurry interacts with at least a portion of electromagnetic radiation.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method for examining a chemical mechanical polishing (CMP) slurry, the method comprising:
transmitting electromagnetic radiation through a sample of the slurry, wherein the slurry interacts with at least a portion of electromagnetic radiation;
measuring an interaction between the electromagnetic radiation and the slurry; and
making a determination regarding the slurry based on the interaction.

2. The method of claim 1, wherein the electromagnetic radiation comprises at least one specific wavelength.

3. The method of claim 2, wherein a component of the slurry absorbs at least a portion of the electromagnetic radiation at the specific wavelength and the interaction is absorbance of the electromagnetic radiation at the specific wavelength.

4. The method of claim 3, wherein making the determination comprises determining a concentration of the component in the slurry.

5. The method of claim 3, wherein the component is a permanganate compound.

6. The method of claim 2, wherein the specific wavelength is in the range of about 500 nm to about 570 nm.

7. The method of claim 2, wherein a component of the slurry scatters at least a portion of the electromagnetic radiation at the specific wavelength and the interaction is scattering of the electromagnetic radiation at the specific wavelength.

8. The method of claim 7, wherein making the determination comprises determining a concentration of the component in the slurry.

9. The method of claim 7, wherein the component is a solid particle species.

10. The method of claim 9, wherein the solid particle species is manganese dioxide.

11. The method of claim 8, wherein determining the concentration of the component comprises comparing the measured scattering to a calibration curve of scattering created for the CMP slurry.

12. The method of claim 4, wherein determining the concentration of the component comprises comparing the measured absorbance to a calibration curve of absorbance created for the CMP slurry.

13. The method of claim 1, wherein the slurry comprises abrasive particles.

14. The method of claim 13, further comprising separating the abrasive particles from an abrasive free sample of the slurry and measuring the interaction using the abrasive free sample.

15. The method of claim 1, wherein the slurry does not comprise abrasive particles.

16. The method of claim 1, wherein the method is performed using a spectrometer.

17. The method of claim 1, wherein the electromagnetic radiation comprises at least a first specific wavelength and a second specific wavelength, wherein a first component of the slurry absorbs at least a portion of the electromagnetic radiation at the first specific wavelength, wherein a second component of the slurry scatters at least a portion of the electromagnetic radiation at the second specific wavelength, wherein the interaction comprises absorbance of the electromagnetic radiation at the first specific wavelength and scattering of the electromagnetic radiation at the second specific wavelength, and wherein making the determination comprises determining a concentration of the first component in the slurry based on the absorbance of the electromagnetic radiation at the first specific wavelength and determining a concentration of the second component in the slurry based on the scattering of the electromagnetic radiation at the second specific wavelength.

18. The method of claim 1, wherein the slurry is a silicon carbide (SiC) CMP slurry.

19. A slurry recycling system, comprising:
a slurry diversion system configured to receive slurry from at least one chemical-mechanical polishing (CMP) tool;
a vessel configured to receive slurry diverted from the at least one CMP tool for reconditioning of the slurry;
a slurry monitoring system configured to transmit electromagnetic radiation through a sample of the slurry, measure an interaction of the electromagnetic radiation with the slurry, and determine if the slurry is suitable for recycling; and
a slurry redistribution system to provide reconditioned slurry to the at least one CMP tool.

20. A slurry monitoring apparatus configured to transmit electromagnetic radiation of a specific wavelength through a sample of a chemical mechanical polishing (CMP) slurry, measure absorbance of the electromagnetic radiation by the slurry, and determine if the slurry is suitable for use.
